(19) United States
(12) Patent Application Publication
(10) Pub. No.: US 2026/0068262 A1
(43) Pub. Date: Mar. 5, 2026

(54) SEMICONDUCTOR DEVICE AND METHODS OF FORMATION

(71) Applicant: Taiwan Semiconductor Manufacturing Company, Ltd., Hsinchu (TW)

(72) Inventors: Kun-Huang YU, Hsinchu County (TW); Ruey-Hsin LIU, Hsin-Chu (TW); Chi-Chih CHEN, Dounan Township (TW); Chih-Chang CHENG, Hsinchu City (TW)

(21) Appl. No.: 18/825,586

(22) Filed: Sep. 5, 2024

(51) Int. Cl. H01L 29/40; H01L 29/08; H01L 29/66; H01L 29/78

(52) U.S. Cl. CPC H10D 64/112; H10D 30/0281; H10D 30/65; H10D 62/151

(57) ABSTRACT

A high-voltage transistor includes a main field plate layer between a gate structure and a drain region of the high-voltage transistor, a blocking layer between the main field plate layer and a substrate layer of the high-voltage transistor, and a pattern field plate structure laterally between the blocking layer and the drain region. The pattern field plate structure may be formed from the same layer(s) as the gate structure and associated gate dielectric layer, which minimizes the cost, complexity, and manufacturing resources for forming the pattern field plate structure. The pattern field plate structure functions as a self-aligned mask for forming the blocking layer, the drain region, and/or a metal silicide layer on the drain region. This enables closer positioning of the blocking layer and a drain contact on the drain region, as well a reduced lateral size of the drain region.

### BACKGROUND

A high-voltage transistor is a type of metal oxide semiconductor (MOS) transistor that may be configured to operate at a higher drain voltage relative to a low voltage transistor. Low voltage transistors may be used in applications such as logic circuits (e.g., processors), memory (e.g., static random access memory (SRAM)), and/or input/output (I/O) circuits, among other examples. High-voltage transistors may be used in applications such as integrated circuit (IC) drivers, power ICs, image sensors, power management, display driver ICs (DDICs), bipolar complementary metal oxide semiconductor (CMOS) diffused metal oxide semiconductor (DMOS) ICs (BCD ICs), and/or image signal processing (ISP) ICs, among other examples.

### BRIEF DESCRIPTION OF THE DRAWINGS

Aspects of the present disclosure are best understood from the following detailed description when read with the accompanying figures. In accordance with the standard practice in the industry, various features may not be drawn to scale. In fact, the dimensions of the various features may be arbitrarily increased or reduced for clarity of discussion.

FIG. 1 is a diagram of an example semiconductor device described herein.

FIGS. 2A and 2B are diagrams of an example implementation of an integrated circuit device described herein.

FIGS. 3A-3R are diagrams of an example implementation of forming an integrated circuit device described herein.

FIG. 4 is a diagram of an example implementation of an integrated circuit device described herein.

FIG. 5 is a diagram of an example implementation of an integrated circuit device described herein.

FIG. 6 is a diagram of an example implementation of an integrated circuit device described herein.

FIG. 7 is a flowchart of an example process associated with forming a semiconductor device described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

To operate at higher drain voltages, a high-voltage transistor may be manufactured to withstand a high breakdown voltage. Breakdown voltage is a voltage at or near which a transistor ceases to operate according to the intended operating principles of the transistor. In a high-voltage transistor, gate-to-drain voltages may sometimes satisfy or exceed the breakdown voltage of the high-voltage transistor due to the high drain voltages experienced by the high-voltage transistor.

In some cases, a high-voltage transistor may be manufactured such that a minimum distance between a gate structure and a drain region of the high-voltage transistor enables a particular breakdown voltage (BV) to be achieved by the high-voltage transistor. Increasing the distance between the gate structure and the drain region provides for greater distribution of an electric field between the gate structure and the drain region, which reduces the peak magnitude of the electric field (thereby increasing the breakdown voltage). Moreover, a field plate layer may be included in the area between the gate structure and the drain region to help control the peak electric field between the gate structure and the drain region.

The area between the gate structure and the drain region is a keep-out area for metal silicide formation, so a blocking layer is formed on a substrate of the high-voltage transistor in this area to block metal silicide formation during formation of a metal silicide layer on the drain region. The field plate layer may be formed on the blocking layer, and the blocking layer provides an additional buffer for the field plate layer to further distribute the electric field between the gate structure and the drain region. However, the blocking layer may be subject to manufacturing rules such as a minimum spacing between the blocking layer and a drain contact for the drain region, and/or a minimum amount of overlap of the blocking layer and the drain region (e.g., to ensure that silicide formation on the substrate is blocked). These manufacturing rules may result in an increased lateral footprint for the high-voltage transistor. Since the specific-on-resistance (R_{on.sp}) of the high-voltage transistor is a function of a resistance of the high-voltage transistor and a device pitch of the high-voltage transistor, the increased lateral footprint due to the blocking layer manufacturing rules may result in greater specific-on-resistance for the high-voltage transistor. The greater specific-on-resistance increases the power consumption and, thus, decreases the operating efficiency of the high-voltage transistor. Moreover, the increased lateral footprint reduces the density of high-voltage transistors that can be integrated onto a semiconductor device without increasing the lateral footprint of the semiconductor device.

In some implementations described herein, a high-voltage transistor includes a main field plate layer between a gate structure and a drain region of the high-voltage transistor, a blocking layer between the main field plate layer and a substrate layer of the high-voltage transistor, and a pattern field plate structure laterally between the blocking layer and the drain region. The pattern field plate structure may be formed from the same layer(s) as the gate structure and associated gate dielectric layer, which minimizes the cost, complexity, and manufacturing resources for forming the pattern field plate structure.

The pattern field plate structure functions as a self-aligned mask for forming the blocking layer, which enables precise control of the lateral coverage of the blocking layer on the substrate layer. The use of the pattern field plate structure enables reduced spacing between the blocking layer and a drain contact on the drain region of the high-voltage transistor structure, which reduces the lateral footprint of the high-voltage transistor structure. Additionally and/or alternatively, the pattern field plate structure functions as a self-aligned mask for forming the drain region and the associated metal silicide layer on the drain region. The use of the pattern field plate structure eliminates the need for the blocking layer to partially overlap the drain region, which enables the lateral width of the drain region to be reduced. The reduced lateral width of the drain region reduces the lateral footprint of the high-voltage transistor structure.

In this way, the reduced lateral footprint of the high-voltage transistor structure enables a lower specific-on-resistance to be achieved for the high-voltage transistor. The reduced specific-on-resistance decreases the power consumption and, thus, increases the operating efficiency of the high-voltage transistor. Moreover, the reduced lateral footprint enables an increased density of high-voltage transistors to be integrated onto a semiconductor device without increasing (or with minimal increase to) the peak electric field between the gate structure and the drain region of the high-voltage transistors.

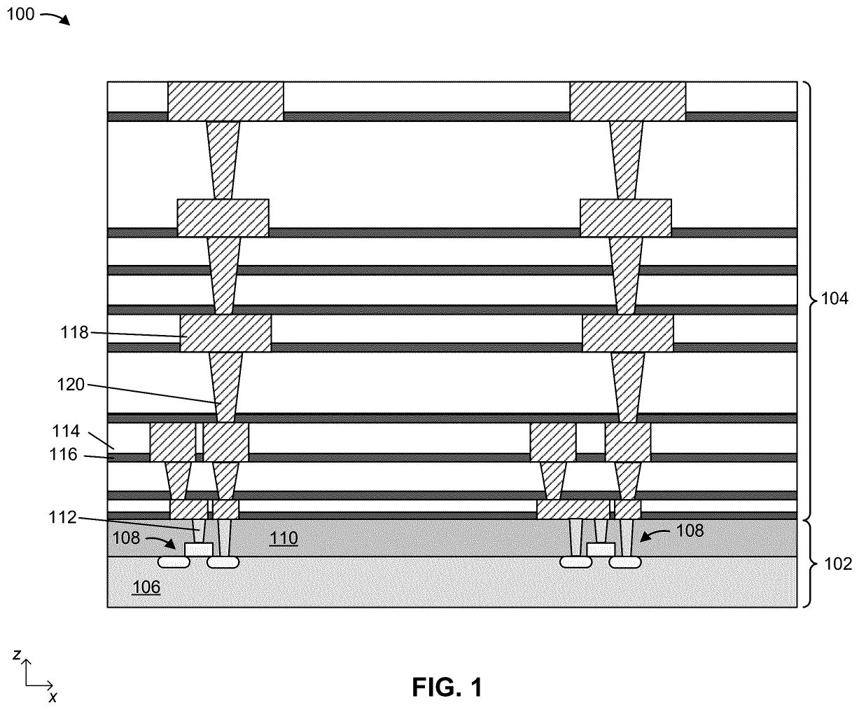

FIG. 1 is a diagram of an example semiconductor device 100 described herein. The semiconductor device 100 may include system on chip (SoC) device, a logic device such as a central processing unit (CPU) or a graphics processing unit (GPU), a memory device (e.g., a high bandwidth memory (HBM) device), a panel driver device, an integrated circuit (IC) driver, a radio frequency (RF) power amplifier, a display driver IC (DDIC), and/or another type of semiconductor device.

As shown in FIG. 1, the semiconductor device 100 may include a device layer 102 and an interconnect layer 104 above the device layer 102 in a z-direction in the semiconductor device 100. The device layer 102 may also be referred to as a frontend region or a front end of line (FEOL) region of the semiconductor device 100. The interconnect layer 104 may also be referred to as a backend region or a back end of line (BEOL) region of the semiconductor device 100.

The device layer 102 includes a substrate layer 106. The substrate layer 106 may correspond to a portion of a semiconductor wafer on which the semiconductor device 100 is formed. The substrate layer 106 includes a silicon (Si) substrate, a substrate formed of a material including silicon, a III-V compound semiconductor material substrate such as gallium arsenide (GaAs), a silicon on insulator (SOI) substrate, or another type of semiconductor substrate. The substrate layer 106 may extend in an x-direction and/or in a y-direction in the semiconductor device 100.

Integrated circuit devices 108 may be included in and/or on the substrate layer 106 in the device layer 102 of the semiconductor device 100. The integrated circuit devices 108 include frontend transistor structures (e.g., frontend planar transistor structures, frontend fin field effect transistor (finFET) structures, frontend gate all around (GAA) transistor structures), pixel sensors, capacitors, resistors, inductors, photodetectors, transceivers, transmitters, receives, optical circuits, and/or other types of frontend semiconductor devices. Frontend semiconductor devices refer to the semiconductor devices that are formed in the device layer 102 (e.g., in and/or on the substrate layer 106) of the semiconductor device 100.

In some implementations, one or more of the integrated circuit devices 108 include a high-voltage transistor (or a medium voltage transistor). “High-voltage transistor” refers to a transistor that is configured to operate at higher operating voltages (e.g., higher gate voltages, higher source/drain voltages) than low voltage transistors. As an example, a high-voltage transistor may be configured to operate in a drain voltage range of approximately 9 volts to approximately 36 volts, whereas a low-voltage transistor may be configured to operate in a drain voltage range of approximately 0 volts to approximately 1.8 volts. However, other values for these ranges are within the scope of the present disclosure.

A high-voltage transistor (or a medium voltage transistor) may include a laterally diffused (or laterally double diffused) metal-oxide semiconductor (LDMOS) transistor that has a drift region in which charge carriers are laterally diffused to facilitate distribution of an electric field between a gate structure and a source/drain region of the high-voltage transistor. The lateral diffusion of charge carriers in the drift region enables the high-voltage transistor to withstand higher gate and source/drain voltages (e.g., by increasing the breakdown voltage of the high-voltage transistor) than low voltage transistors.

A dielectric layer 110 is included over the substrate layer 106. The dielectric layer 110 includes an interlayer dielectric (ILD) layer, an etch stop layer (ESL), and/or another type of dielectric layer. The dielectric layer 110 includes dielectric material(s) that enable various portions of the substrate layer 106 and/or the integrated circuit devices 108 to be selectively etched or protected from etching, and/or to electrically isolate the integrated circuit devices 108 in the device layer 102. The dielectric layer 110 includes a silicon nitride (SixNy), an oxide (e.g., a silicon oxide (SiOₓ) and/or another oxide material), and/or another type of dielectric material. The dielectric layer 110 may extend in the x-direction and/or in a y-direction in the semiconductor device 100.

The interconnect layer 104 of the semiconductor device 100 is included above the substrate layer 106 and above the integrated circuit devices 108 in the z-direction in the semiconductor device 100. The integrated circuit devices 108 may be electrically coupled to the interconnect layer 104 by contact structures 112. In some implementations, an integrated circuit device 108 may be electrically coupled to gate contacts and source/drain contacts. The contact structures 112 may include contact plugs, vias, pillars, contact pads, and/or another type of electrically conductive contacts. The contact structures 112 may include one or more electrically conductive materials such as tungsten (W), cobalt (Co), ruthenium (Ru), titanium (Ti), an alloy thereof, a metal nitride that contains one or more metals, and/or another electrically conductive material. In some implementations, a liner is included between a contact structure 112 and the dielectric layer 110. The liner may include an adhesion liner, a barrier liner, and/or another type of liner, and may include liner materials such as tantalum (Ta), tantalum nitride (TaN), and/or titanium nitride (TiN), among other examples.

The interconnect layer 104 includes a plurality of dielectric layers (e.g., backend dielectric layers) that are arranged in a direction (e.g., the z-direction) that is approximately perpendicular to the substrate layer 106. The dielectric layers may include ILD layers 114 and ESLs 116 that are arranged in an alternating manner in the z-direction. The ILD layers 114 and the ESLs 116 may extend in the x-direction and/or in the y-direction in the semiconductor device 100.

The ILD layers 114 may each include an oxide (e.g., a silicon oxide (SiOₓ) and/or another oxide material), an undoped silicate glass (USG), a boron-containing silicate glass (BSG), a fluorine-containing silicate glass (FSG), tetraethyl orthosilicate (TEOS), hydrogen silsesquioxane (HSQ), and/or another suitable dielectric material. In some implementations, an ILD layer 114 includes an extreme low dielectric constant (ELK) dielectric material having a dielectric constant that is less than approximately 2.5. Examples of ELK dielectric materials include carbon doped silicon oxide (C—SiOₓ), amorphous fluorinated carbon (α-CₓF_{y}), parylene, bis-benzocyclobutenes (BCB), polytetrafluoroethylene (PTFE), a silicon oxycarbide (SiOC) polymer, porous hydrogen silsesquioxane (HSQ), porous methyl silsesquioxane (MSQ), porous polyarylether (PAE), and/or porous silicon oxide (SiOₓ), among other examples.

The ESLs 116 may each include a silicon nitride (SiₓN_{y}), silicon carbide (SiC), silicon oxynitride (SiON), and/or another suitable dielectric material. In some implementations, an ILD layer 114 and an ESL 116 include different dielectric materials to provide etch selectivity to enable various structures to be formed in the interconnect layer 104.

The interconnect layer 104 includes a plurality of conductive structures. One or more of the conductive structures are electrically coupled and/or physically coupled with one or more of the integrated circuit devices 108 (e.g., with the contact structures 112 of the integrated circuit devices 108) in the device layer 102. The conductive structures provide electrical routing that enables signals and/or power to be provided to and/or from the integrated circuit devices 108. The conductive structures may include a combination of metallization structures 118 and interconnect structures 120. The metallization structures 118 may include trenches, metallization layers, conductive traces, and/or other types of metallization structures. The interconnect structures 120 may include vias, plugs, interconnects, and/or another type interconnect structures. The metallization structures 118 and the interconnect structures 120 may one or more electrically conductive materials such as tungsten (W), cobalt (Co), ruthenium (Ru), titanium (Ti), aluminum (Al), copper (Cu), gold (Au), and/or a combination thereof, among other examples of electrically conductive materials. In some implementations, one or more liner layers are included on the metallization structures 118 and the interconnect structures 120. The one or more liner layers may include barrier liners, adhesion liners, and/or another type of liners. Examples of materials for the one or more liners include tantalum nitride (TaN) and/or titanium nitride (TiN), among other examples.

In some implementations, the metallization structures 118 and the interconnect structures 120 of the interconnect layer 104 may be arranged in in a vertical manner (e.g., in the z-direction). In other words, a plurality of stacked metallization structures 118 and interconnect structures 120 extend between the device layer 102 and a top of the interconnect layer 104 to facilitate electrical signals and/or power to be routed between the device layer 102 and connection structures (not shown) of the semiconductor device 100. The plurality of stacked metallization structures 118 may be arranged in layers referred to as M-layers. For example, a metal-0 (M0) layer may located at the bottom of the interconnect layer 104 and may be directly coupled with the device layer 102 (e.g., with the contact structures 112 of the integrated circuit devices 108 in the device layer 102). A via-1 (V1) layer that includes one or more interconnect structures 120 may be included above the M0 layer. A metal-1 layer (M1) layer may be located above the V1 layer in the interconnect layer 104, a via-2 (V2) layer may be included above the M1 layer, a metal-2 layer (M2) layer may be located above the V2 layer, and so on. Additionally, via layers may be included between vertically arranged M-layers.

As indicated above, FIG. 1 is provided as an example. Other examples may differ from what is described with regard to FIG. 1.

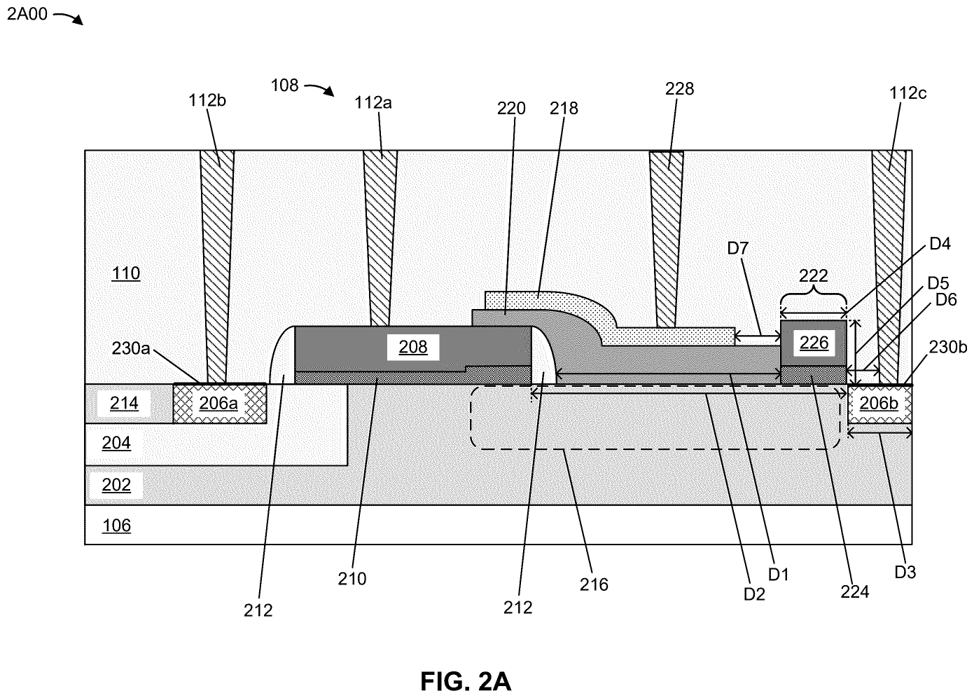

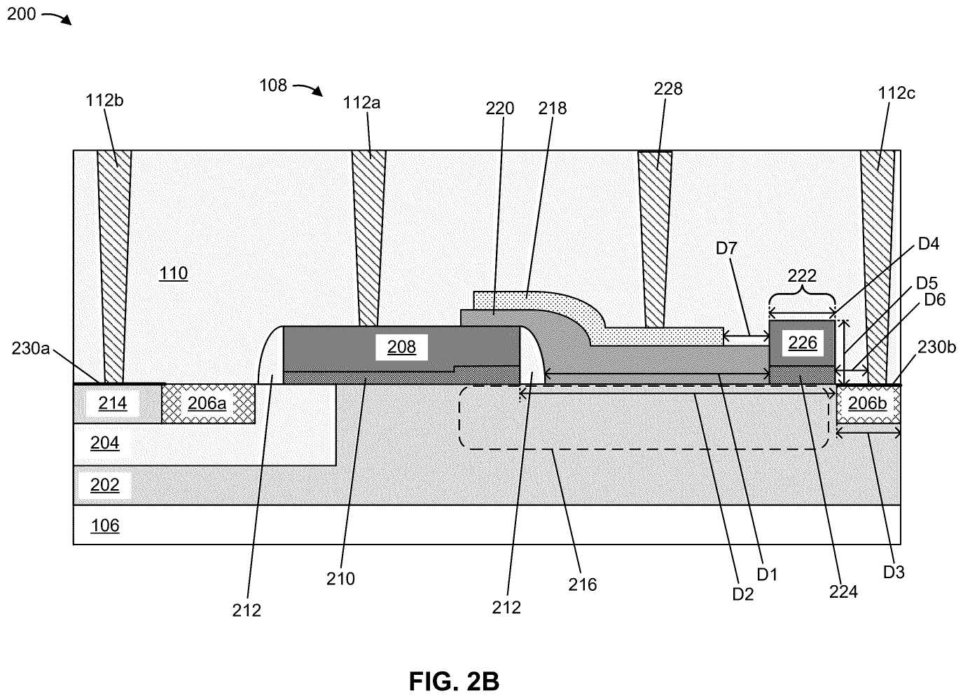

FIGS. 2A and 2B are diagrams of an example implementation 200 of an integrated circuit device 108 described herein. In the example implementation 200, the integrated circuit device 108 includes a high voltage transistor such as an LDMOS transistor.

As shown in FIGS. 2A and 2B, the integrated circuit device 108 may include (or may be included on) the substrate layer 106 of the semiconductor device 100. The integrated circuit device 108 may include an active region 202 in the substrate layer 106, a bulk region 204 in the substrate layer 106, a source/drain region 206a in the bulk region 204, a source/drain region 206b in the active region 202, and a gate structure 208 on the active region 202.

The active region 202 may include a region of the substrate layer 106 in which the integrated circuit device 108 operates. The active region 202 may include a doped region of the substrate layer 106 that is doped with one or more types of dopants, such as p-type dopants and/or n-type dopants. The active region 202 includes one or more semiconductor materials such that the conductivity of the active region 202 may be selectively controlled using an electric field. In this way, an electrical current may selectively flow between the source/drain region 206a and the source/drain region 206b based the electrical conductivity of the active region 202. A voltage may be selectively applied to the gate structure 208 to selectively control the conductivity of the active region 202 in the substrate layer 106.

The source/drain region 206a may be located on a first side (e.g., laterally adjacent to the first side) of the gate structure 208, and the source/drain region 206b may be located on a second side (e.g., laterally adjacent to the second side) of the gate structure 208 opposing the first side. A source/drain region may refer to a source region, a drain region, or a combination of a source and drain region, depending on the context. In some implementations, the source/drain region 206a is a source region of the integrated circuit device 108 and the source/drain region 206b is a drain region of the integrated circuit device 108 that is configured to operate at a relatively high voltage such as up to approximately 36 volts.

The source/drain regions 206a and 206b may each include one or more doped regions of the substrate layer 106. In some implementations, the source/drain regions 206a and 206b may include the same dopant type. For example, the source/drain regions 206a and 206b may each include silicon doped with one or more p-type dopants such as boron (B) and/or gallium (Ga), among other examples. As another example, the source/drain regions 206a and 206b may each include silicon doped with one or more n-type dopants such as arsenic (A) and/or phosphorous (P), among other examples. In some implementations, the source/drain regions 202a and 202b include different dopant types. For example, the source/drain region 206a may include silicon doped with one or more p-type dopants, and the source/drain region 206b may include silicon doped with one or more n-type dopants.

The gate structure 208 may be located on the substrate layer 106 laterally between the source/drain regions 206a and 206b. In some implementations, the gate structure 208 includes a polysilicon gate. In some implementations, the gate structure 208 includes a metal gate and includes one or more metal materials such as tungsten (W), titanium (Ti), titanium aluminum (TiAl), and/or other suitable metal materials.

A gate dielectric layer 210 may be included on the substrate layer 106 between the substrate layer 106 and the gate structure 208. In some implementations, a portion of the gate dielectric layer 210 is located on the bulk region 204 and another portion is included on the active region 202. The gate dielectric layer 210 may provide electrical isolation between the gate structure 208 and the substrate layer 106, which enables a voltage applied to the gate structure 208 to cause an electric field to be generated in the substrate layer 106. In some implementations, the gate dielectric layer 210 may include a low dielectric constant (low-k) dielectric material such as a silicon oxide (SiOₓ such as SiO₂). Additionally and/or alternatively, the gate dielectric layer 210 may include a high dielectric constant (high-k) dielectric material (e.g., a dielectric material having a dielectric constant that is greater than approximately 3.9) such as a silicon nitride (SiₓN_{y} such as Si₃N₄), a hafnium oxide (HfOₓ such as HfO₂), and/or aluminum oxide (AlₓO_{y} such as Al₂O₃), among other examples.

One or more sidewall spacers 212 may be included over and/or on sidewalls of the gate structure 208. The sidewall spacers 212 may include a silicon oxycarbide (SiOC), a nitrogen free SiOC, or another suitable dielectric material. The sidewall spacers 212 may have a curved or rounded outer surface as a result of a directional (e.g., vertical) etch technique that is used to form the sidewall spacers 212.

A body implant region 214 may be included in the bulk region 204 of the substrate layer 106 next to the source/drain region 206a. The body implant region 214 and the source/drain region 206a may be doped with opposing dopant types (e.g., the source/drain region 206a may be doped with n-type dopants and the body implant region 214 may be doped with p-type dopants). An electrical bias is applied to the body implant region 214 to create a body bias in the substrate layer 106 to compensate for shifts or changes in the threshold voltage (Vt) of the integrated circuit device 108.

As shown in FIGS. 2A and 2B, a drift region 216 may correspond to a portion of the active region 202 between the gate structure 208 and the source/drain region 206b. During operation of the integrated circuit device 108, a depletion region may be formed in the drift region 216. In the depletion region, the magnitude (or intensity) of an electric field formed in the active region 202 is non-uniform between the gate structure 208 and the source/drain region 206b. The magnitude of the electric field in the depletion region may be highest near the gate structure 208, and may decrease from the gate structure 208 to the source/drain region 206b. If the magnitude of the electric field near the gate structure 208 reaches the critical breakdown field of the integrated circuit device 108 (e.g., the maximum electric field at breakdown), the breakdown voltage of the integrated circuit device 108 may be exceeded.

To suppress the peak magnitude of the electric field in the drift region 216 so at to achieve a higher breakdown voltage for the integrated circuit device 108, a main field plate layer may be included above the drift region 216 between the gate structure 208 and the source/drain region 206b. The main field plate layer 218 may extend along the substrate layer 106 between the gate structure 208 and the source/drain region 206b, and in some implementations may extend over a portion of the gate structure 208 and a portion of the sidewall spacer 212 on the sidewall of the gate structure 208.

The main field plate layer 218 may be electrically biased to evenly distribute the magnitude of the electric field across the drift region 216, which reduces the peak magnitude of the electric field in the integrated circuit device 108. The main field plate layer 218 may include a metal such as copper (Cu), gold (Au), silver (Ag), nickel (Ni), tin (Sn), tantalum (Ta), ruthenium (Ru), cobalt (Co), tungsten (W), titanium (Ti), and/or another metal. Additionally and/or alternatively, the main field plate layer 218 may include a metal nitride material (e.g., titanium nitride (TiN), tungsten nitride (WN), tantalum nitride (TaN), a metal oxide (e.g., titanium oxide (TiO₂)), and/or another type of metal-containing material.

A blocking layer 220 may be included between the substrate layer 106 (e.g., the drift region 216 in the substrate layer 106) and the main field plate layer 218. The blocking layer 220 may include a resist-protection oxide (RPO) layer that is included to prevent metal silicide formation on the substrate layer 106, on the gate structure 208, and/or on surfaces of the integrated circuit device 108 other than on the source/drain regions 202a and/or 202b. The blocking layer 220 may also provide a vertical buffer for the main field plate layer 218, which enables the electric field to be further distributed across a greater area for electric field distribution tuning. The blocking layer 220 may include one or more dielectric materials, such as an oxide (e.g., SiOₓ such as SiO₂), a nitride (e.g., SiₓN_{y} such as Si₃N₄), a carbide, an oxynitride, an oxycarbide, and a nitride carbide, a polymer, and/or another suitable dielectric material.

As further shown in FIGS. 2A and 2B, a pattern field plate structure 222 may be included on the substrate layer 106 laterally between the blocking layer 220 and the source/drain region 206b. The pattern field plate structure 222 may be included as a self-aligned mask for forming the blocking layer 220 and/or for forming a metal silicide layer on the source/drain region 206b. In particular, the pattern field plate structure 222 may define a lateral position of an end of the blocking layer 220 that faces the source/drain region 206b, and/or may define a lateral position of an end of the metal silicide layer on the source/drain region 206b facing the blocking layer 220. Thus, a first side of the pattern field plate structure 222 may be adjacent to, and in direct physical contact with, the end of the blocking layer 220 facing the source/drain region 206b, and a second side of the pattern field plate structure 222 may be adjacent to the source/drain region 206b. In some implementations, the first side of the pattern field plate structure 222 is spaced apart from the end of the main field plate layer 218 facing the source/drain region 206b. In some implementations, the first side of the pattern field plate structure 222 is in direct physical contact with the end of the main field plate layer 218 facing the source/drain region 206b.

The pattern field plate structure 222 provides a well-defined barrier between the blocking layer 220 and the source/drain region 206b so that parameters such as the distance between the end of the blocking layer and a contact structure of the source/drain region 206b, and/or the formation of the metal silicide layer on the source/drain region 206b, can be highly controlled.

In some implementations, the pattern field plate structure 222 is formed from the same layers as gate structure 208 and the gate dielectric layer 210 to minimize the impact to the cost, time, and/or complexity of forming the integrated circuit device 108. Accordingly, the pattern field plate structure 222 may include a dielectric layer 224 on the substrate layer 106 and a metal layer (or polysilicon layer) 226 on the dielectric layer 224. The gate dielectric layer 210 and the dielectric layer 224 may be formed from the same dielectric layer, and the gate structure 208 and the metal layer 226 may be formed from the same metal layer (or the same polysilicon layer). Alternatively, the pattern field plate structure 222 may include another material composition, such as a monolithic dielectric structure or a monolithic metal (or polysilicon) structure, among other examples.

As further shown in FIGS. 2A and 2B, the dielectric layer 110 may be included over the integrated circuit device 108. A field plate contact 228 may extend through the dielectric layer 110 and may be included on the main field plate layer 218. A bias voltage may be applied to the main field plate layer 218 through the field plate contact 232 to reduce the peak electric field in the drift region 216. The bias voltage increases carrier depletion in the drift region 216, thereby reducing the peak electric field strength in the drift region 216. By manipulating the electric field, the integrated circuit device 108 can achieve increased breakdown voltages.

A contact structure 112a (e.g., a gate contact) may be included in the one or more dielectric layers and may be electrically connected and/or physically connected with the gate structure 208. As shown in FIG. 2A, contact structures 112b and 112c (e.g., source/drain contacts) may be included in the dielectric layer 110 and may be electrically connected and/or physically connected with the source/drain regions 206a and 206b, respectively. Alternatively, and as shown in FIG. 2B, the contact structure 112b may be physically connected with the body implant region 214. In implementations in which the source/drain region 206 and the body implant region 214 are electrically connected together a source-body voltage (V_{SB}) to be applied to both the source/drain region 206a and the body implant region 214 through the contact structure 112b.

As further shown in FIGS. 2A and 2B, metal silicide layers 230a and 230b may be included on the source/drain regions 206a and 206b of the integrated circuit device 108, respectively. The metal silicide layers 230a and 230b may each include a titanium silicide (TiSi), a ruthenium silicide (RuSi), and/or another type of metal silicide material. The metal silicide layers 230a and 230b provide a transition between the semiconductor material of the source/drain regions 206a and 206b and metal material of the contact structures 112b and 112c that are respectively formed on the source/drain regions 206a and 206b. The metal silicide layers 230a and 230b enable a low contact resistance to be achieved between the contact structures 112b, 112c and the source/drain regions 206a, 206b.

As further shown in FIGS. 2A and 2B, the integrated circuit device 108 may have one or more dimensions. An example dimension D1 may correspond to a lateral distance between the edge of the pattern field plate structure 222 facing the gate structure 208 and the sidewall spacer 212 on the sidewall of the gate structure 208 facing the source/drain region 206b. The dimension D1 may also correspond to a lateral length of the portion of the blocking layer 220 on the substrate layer 106 between the gate structure 208 and the source/drain region 206b. In some implementations, the dimension D1 is included in a range of approximately 200 nanometers to approximately 500 nanometers. A sufficiently high breakdown voltage may not be achieved for the integrated circuit device if the dimension D1 is less than approximately 200 nanometers, whereas a sufficiently low specific-on-resistance may not be achieved for the integrated circuit device if the dimension D1 is greater than approximately 500 nanometers. However, other values and ranges other than approximately 200 nanometers to approximately 500 nanometers for the dimension D1 are within the scope of the present disclosure. In some implementations, the lateral distance between the pattern field plate structure 222 and the sidewall spacer 212 is less than a distance (indicated in FIGS. 2A and 2B as a dimension D2) between the source/drain region 206b and the gate structure 208.

Another example dimension D3 may correspond to a lateral length (or width) of the source/drain region 206b. In some implementations, the dimension D3 is included in a range of approximately 100 nanometers to approximately 200 nanometers. The source/drain region 206b may be susceptible to high process variation if the dimension D3 is less than approximately 100 nanometers, whereas a sufficiently low specific-on-resistance may not be achieved for the integrated circuit device if the dimension D3 is greater than approximately 200 nanometers. However, other values and ranges other than approximately 100 nanometers to approximately 200 nanometers for the dimension D3 are within the scope of the present disclosure.

Another example dimension D4 may correspond to a lateral length (or width) of the pattern field plate structure 222. In some implementations, the dimension D4 is included in a range of approximately 50 nanometers to approximately 200 nanometers. The likelihood of the blocking layer 220 encroaching on the source/drain region 206b may increase if the dimension D3 is less than approximately 50 nanometers, whereas a sufficiently low specific-on-resistance may not be achieved for the integrated circuit device if the dimension D4 is greater than approximately 200 nanometers. However, other values and ranges other than approximately 100 nanometers to approximately 200 nanometers for the dimension D4 are within the scope of the present disclosure. In some implementations, the lateral length of the pattern field plate structure 222 (dimension D4) is less than a length of the gate structure 208.

Another example dimension D5 may correspond to a vertical thickness (or height) of the pattern field plate structure 222. Since the pattern field plate structure 222 may be formed from the same layers as the gate structure 208 and the gate dielectric layer 210, the dimension D5 may correspond to a combined vertical thickness (or height) of the gate structure 208 and the gate dielectric layer 210. However, other values and ranges for the dimension D5 are within the scope of the present disclosure.

Another example dimension D6 may correspond to a lateral distance between the edge of the pattern field plate structure 222 facing the source/drain region 206b and the contact structure 112c on the source/drain region 206b. In some implementations, the dimension D6 is included in a range of approximately 20 nanometers to approximately 100 nanometers. The lateral width (or length) of the source/drain region 206b may not be sufficiently large to handle the high drain voltages of the integrated circuit device 108 if the dimension D5 is less than approximately 20 nanometers, whereas a sufficiently low specific-on-resistance may not be achieved for the integrated circuit device if the dimension D6 is greater than approximately 100 nanometers. However, other values and ranges other than approximately 20 nanometers to approximately 100 nanometers for the dimension D6 are within the scope of the present disclosure.

Another example dimension D7 may correspond to a lateral distance between the edge of the pattern field plate structure 222 facing the gate structure 208 and the edge of the main field plate layer 218 facing the source/drain region 206b. In some implementations, the dimension D7 is included in a range of approximately 0 nanometers to approximately 100 nanometers. The lateral spacing between the main field plate layer 218 the dimension D7 is less than approximately 0 nanometers, whereas a sufficiently high breakdown voltage may not be achieved for the integrated circuit device if the dimension D7 is greater than approximately 100 nanometers. However, other values and ranges other than approximately 0 nanometers to approximately 100 nanometers for the dimension D7 are within the scope of the present disclosure. In some implementations, the distance between the pattern field plate structure 222 and the main field plate layer 218 (dimension D7) is less than the distance between the pattern field plate structure 222 and the contact structure 112c (dimension D6).

In this way, the integrated circuit device 108 includes a blocking layer 220 on the substrate layer 106 between the gate structure 208 and the source/drain region 206b, a main field plate layer 218 on the blocking layer 220, and a pattern field plate structure 222 on the substrate layer 106 laterally between the blocking layer 220 and the source/drain region 206b. A first end of the blocking layer 220 may be located over the gate structure 208, and a second end of the blocking layer 220 opposing the first end may be in physical contact with the pattern field plate structure 222. The pattern field plate structure 222 may be used as a self-aligned pattern for forming the blocking layer 220 such that precise control of the distance between the blocking layer 220 and the contact structure 112c of the source/drain region 206b can be achieved. Moreover, the pattern field plate structure 222 may be used as a self-aligned pattern for forming the metal silicide layer 230b on the source/drain region 206b such that precise control over the formation of the metal silicide layer 230b only on the source/drain region 206b can be achieved. In this way, the pattern field plate structure 222 can compensate for process variations that might otherwise occur when forming the blocking layer 220 and/or when forming the metal silicide layer 230b, which enables the lateral footprint of the integrated circuit device 108 to be reduced. The reduced lateral footprint of the integrated circuit device 108 enables a lower specific-on-resistance to be achieved for the integrated circuit device 108 (which increases the operating efficiency of the integrated circuit device 108) and/or enables a greater density of integrated circuit devices 108 to be included in the semiconductor device 100.

As indicated above, FIGS. 2A and 2B are provided as examples. Other examples may differ from what is described with regard to FIGS. 2A and 2B.

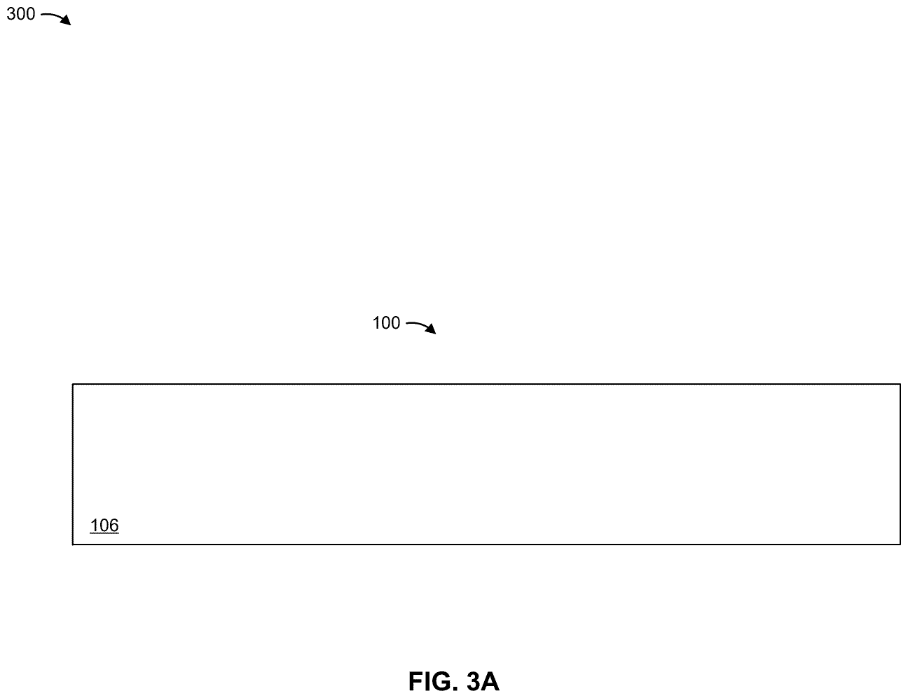

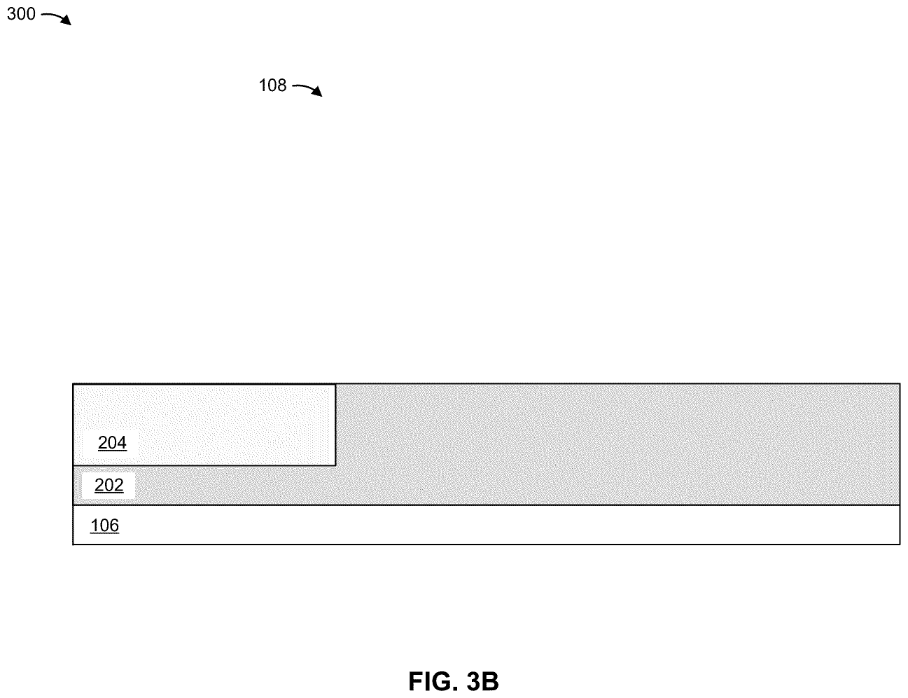

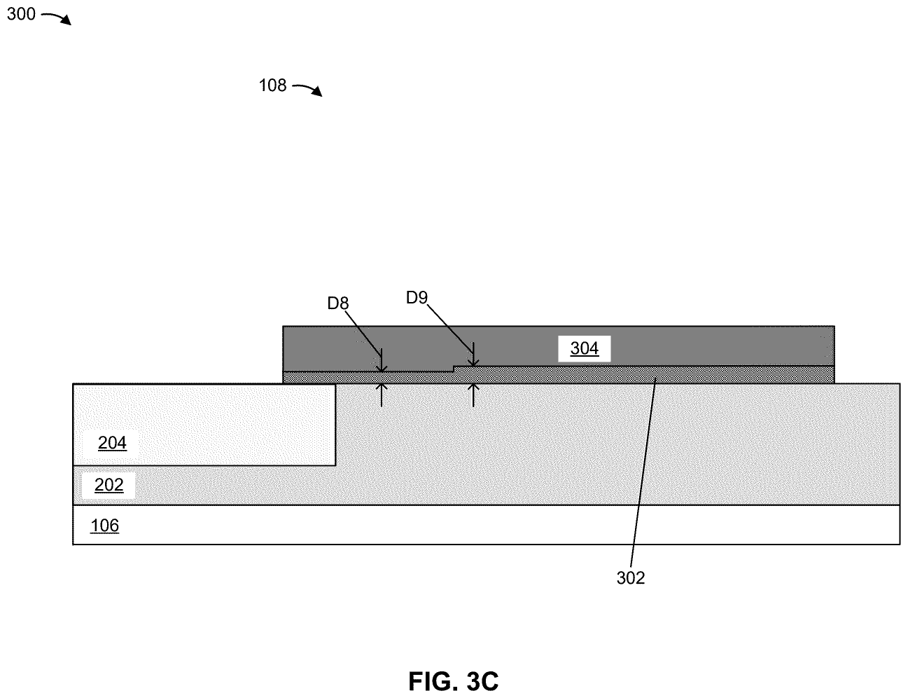

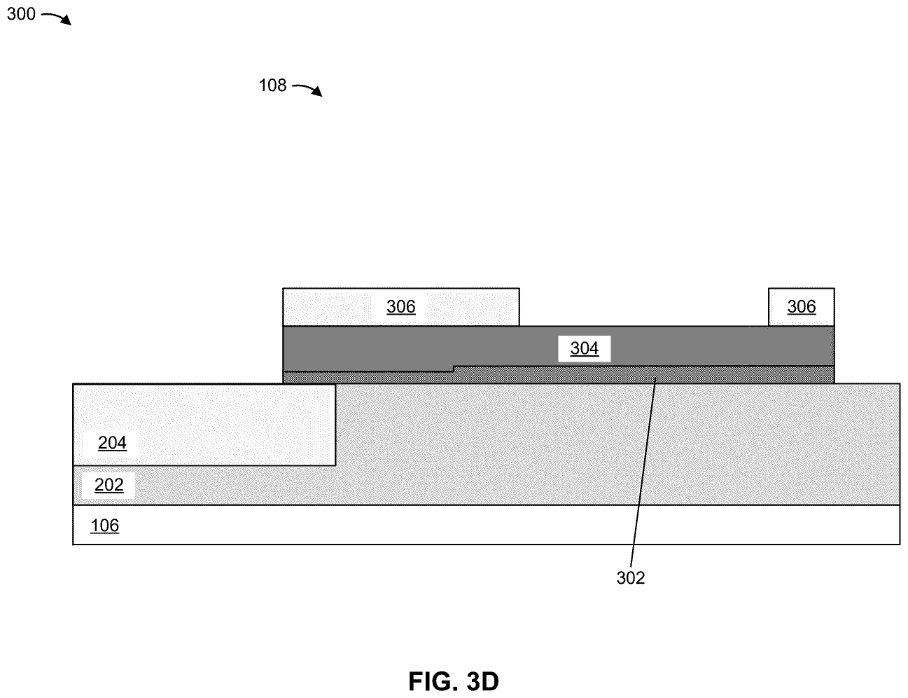

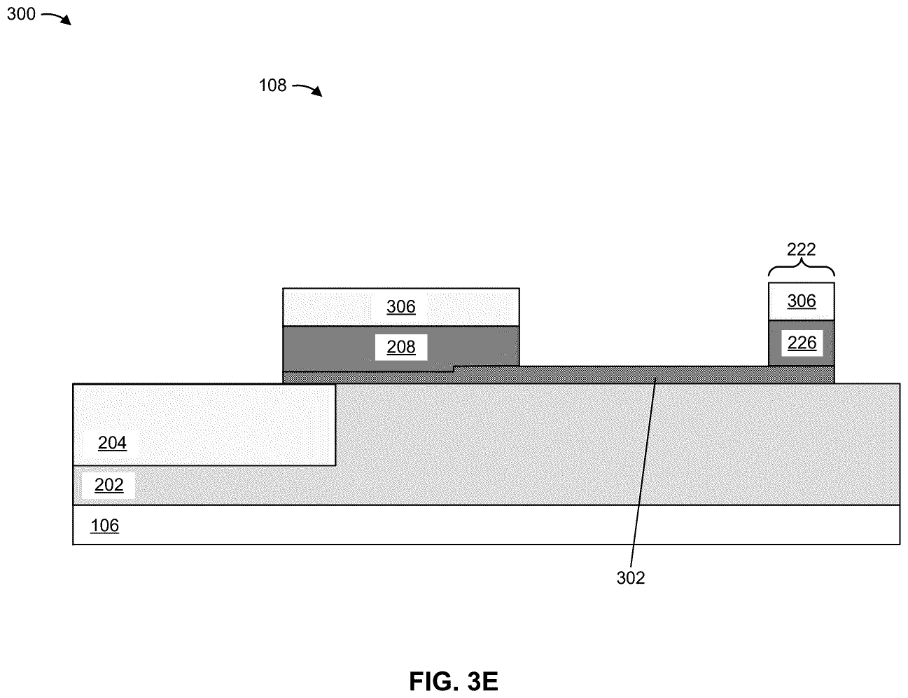

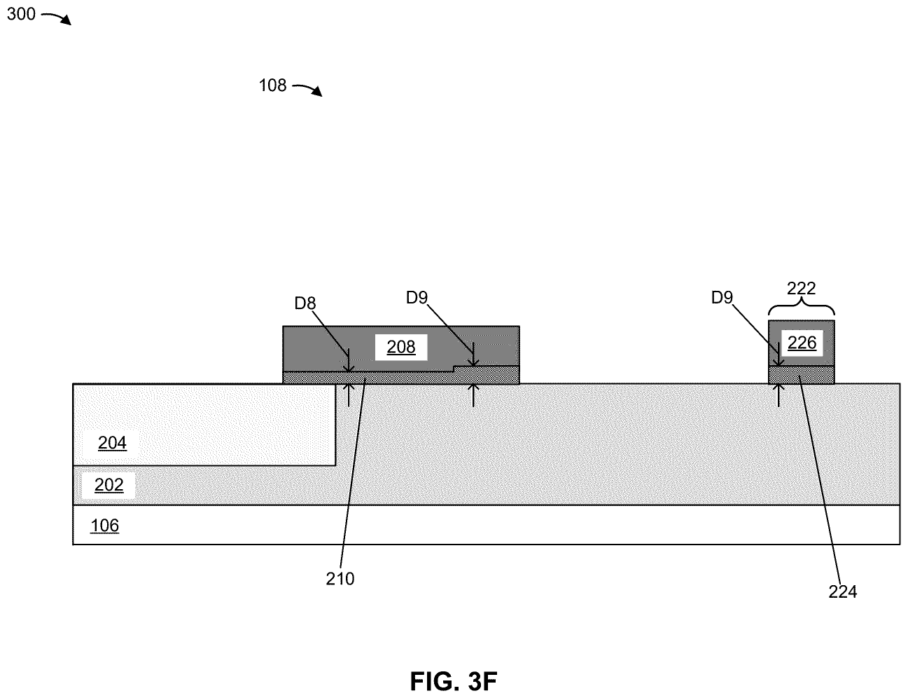

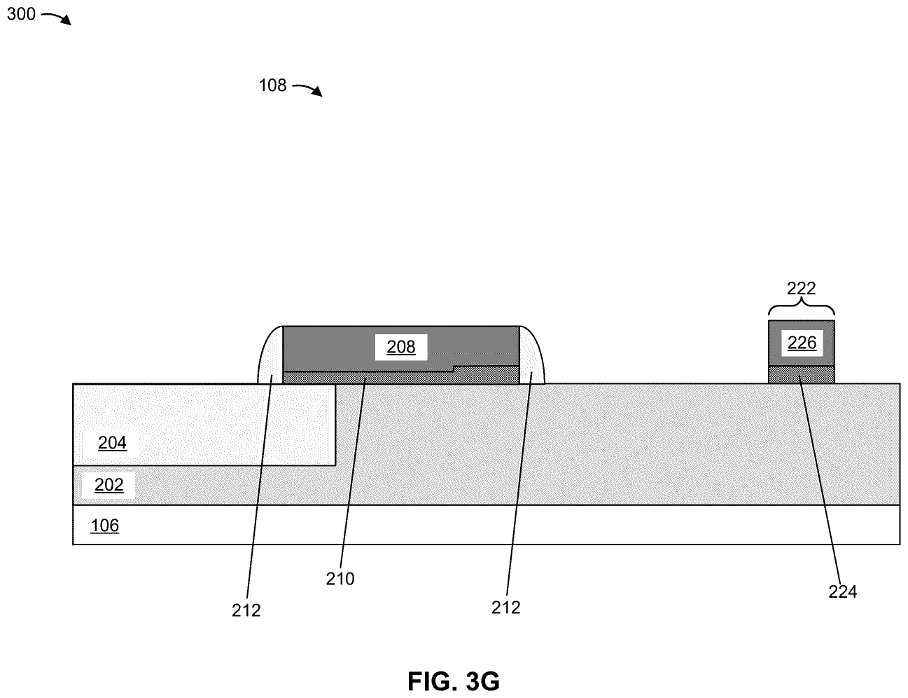

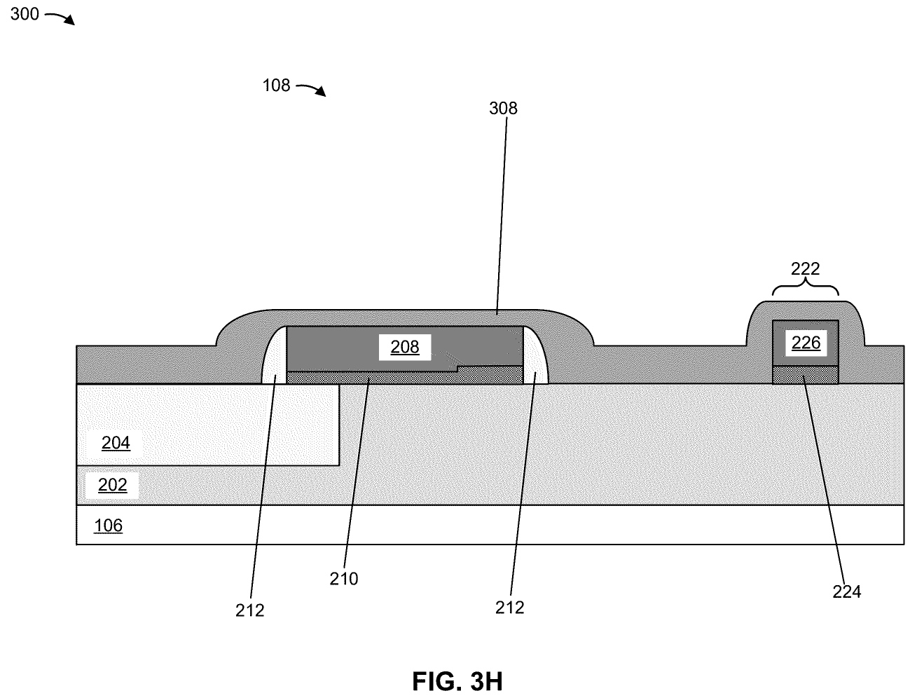

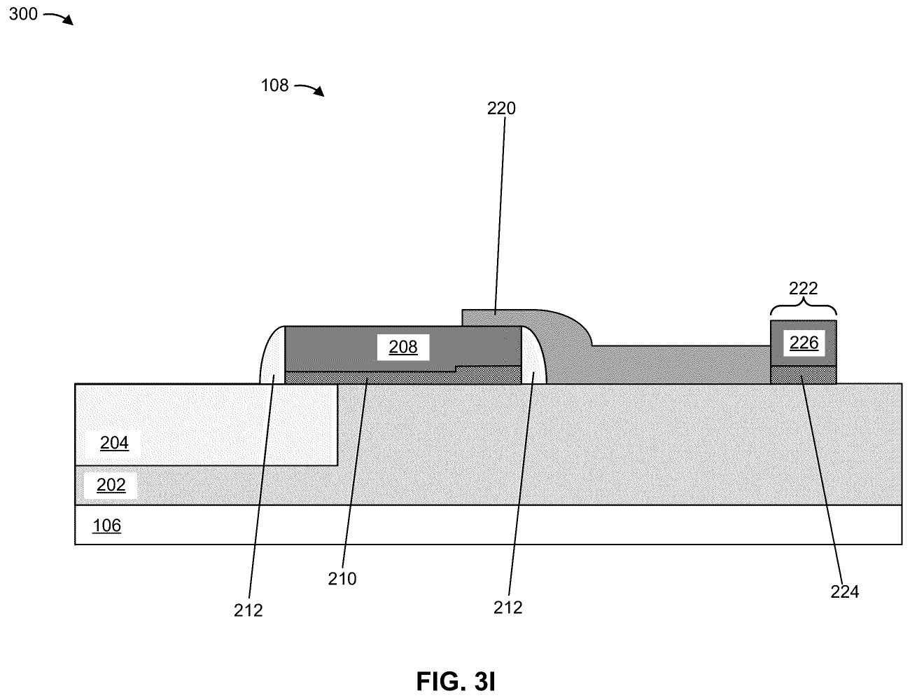

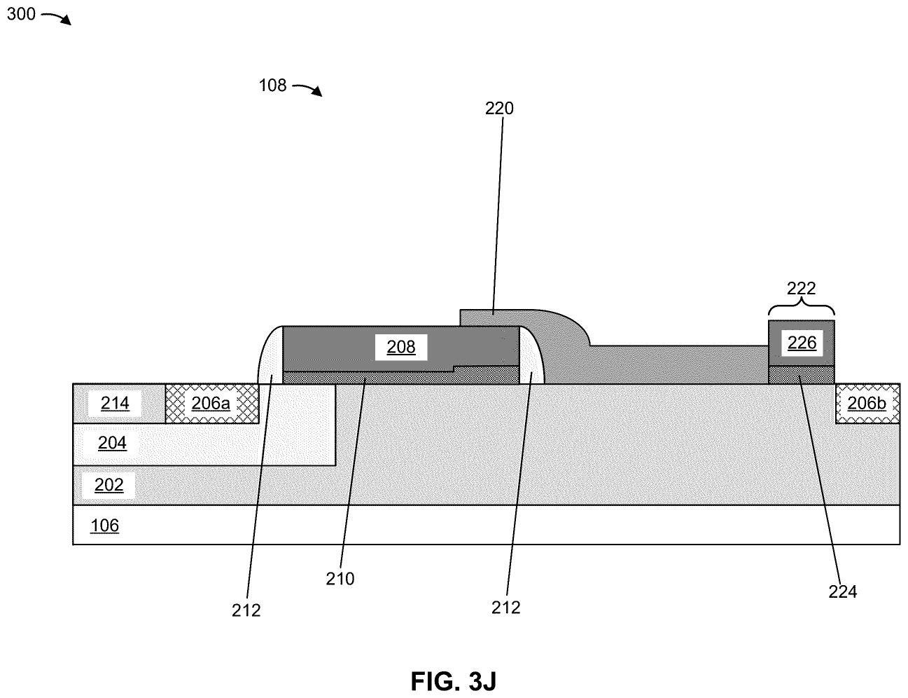

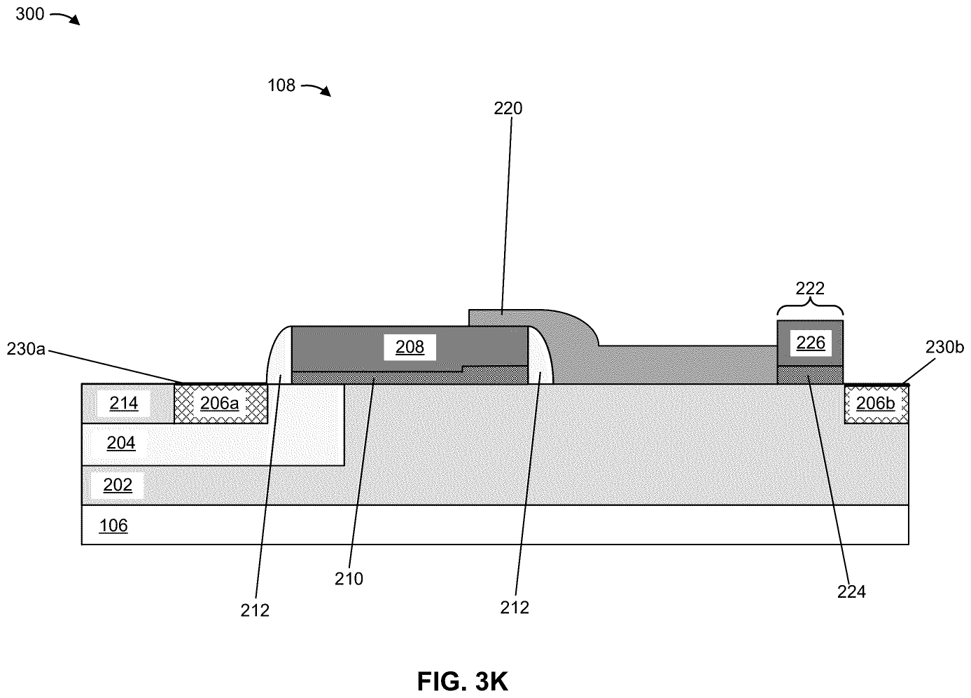

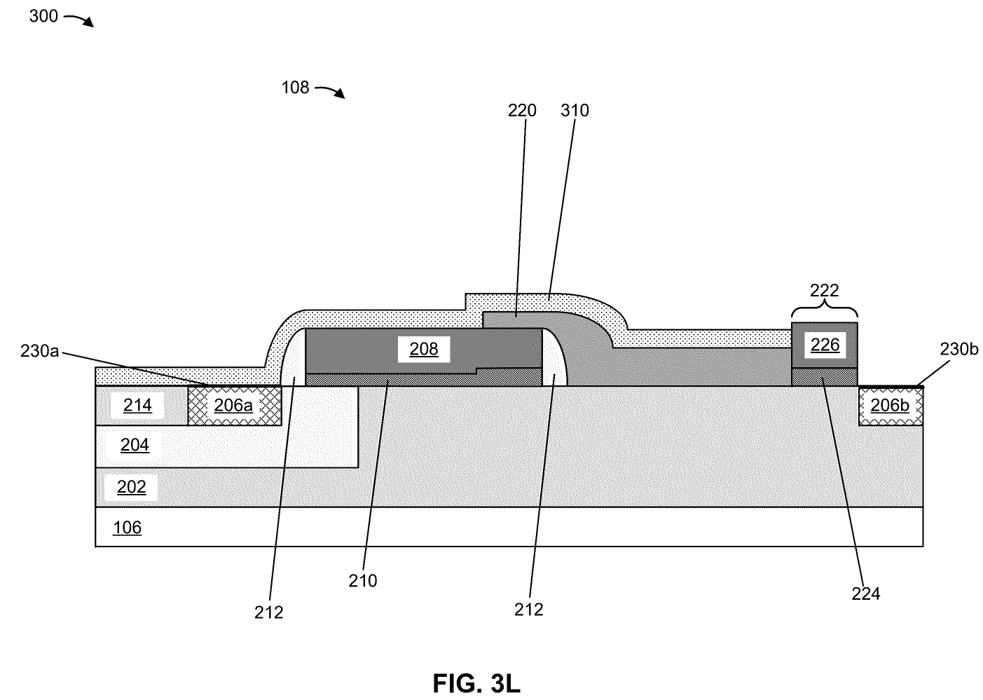

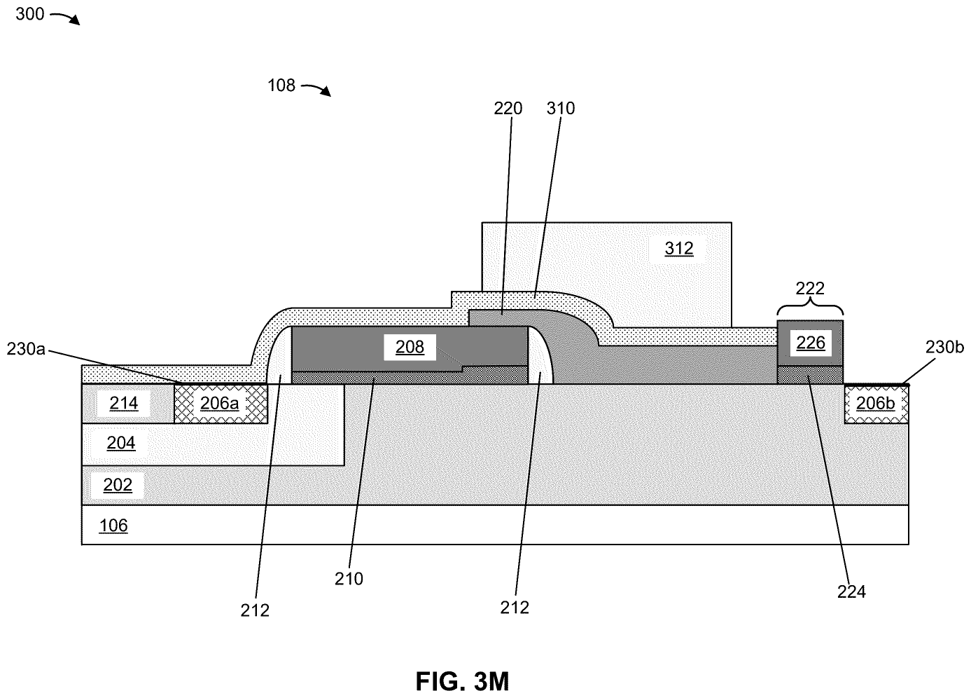

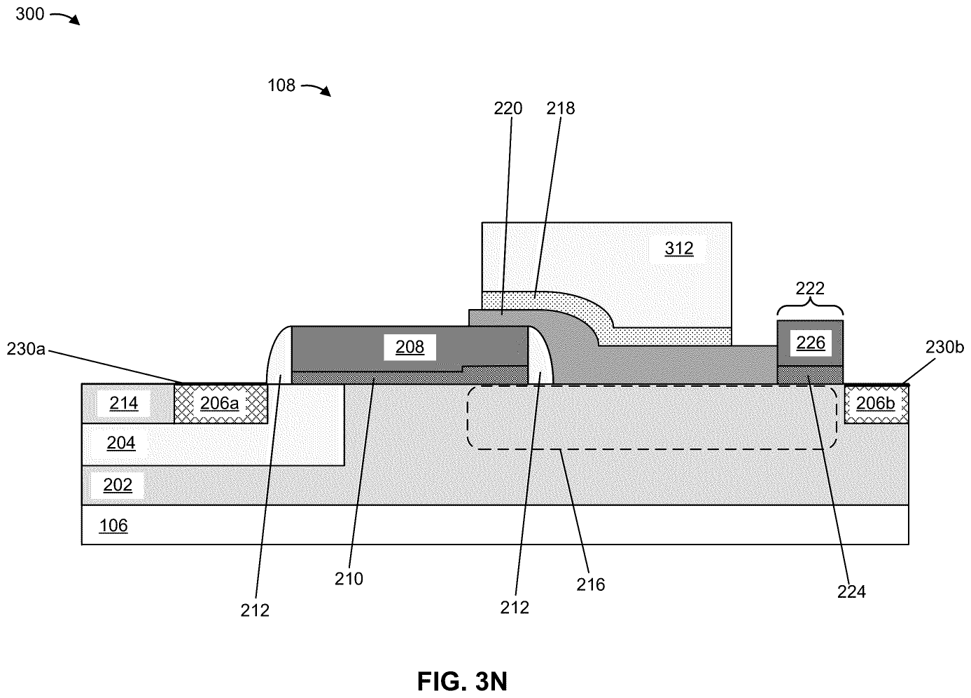

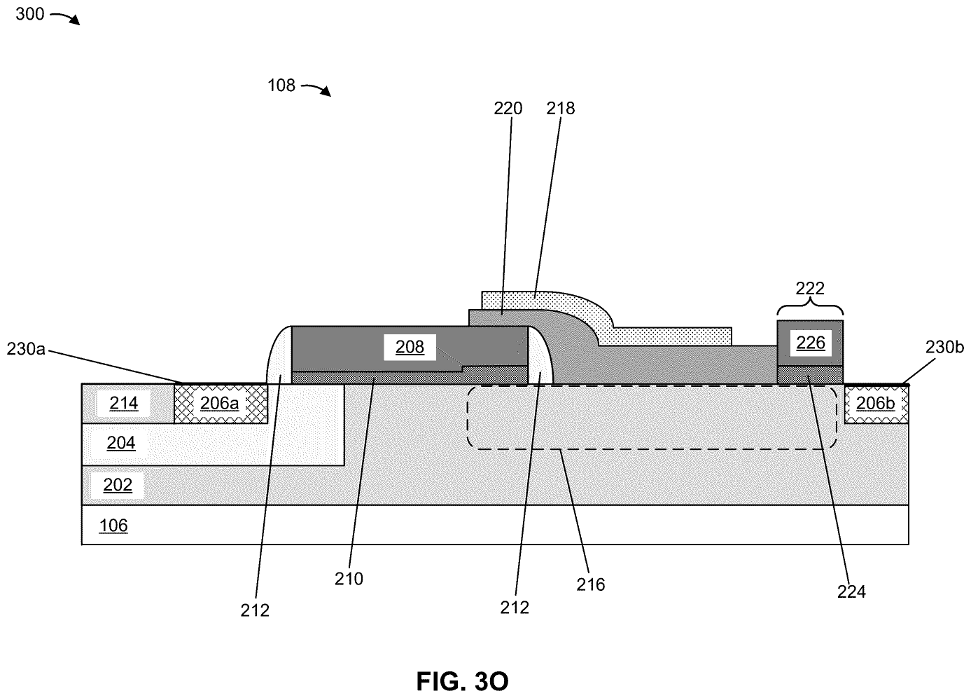

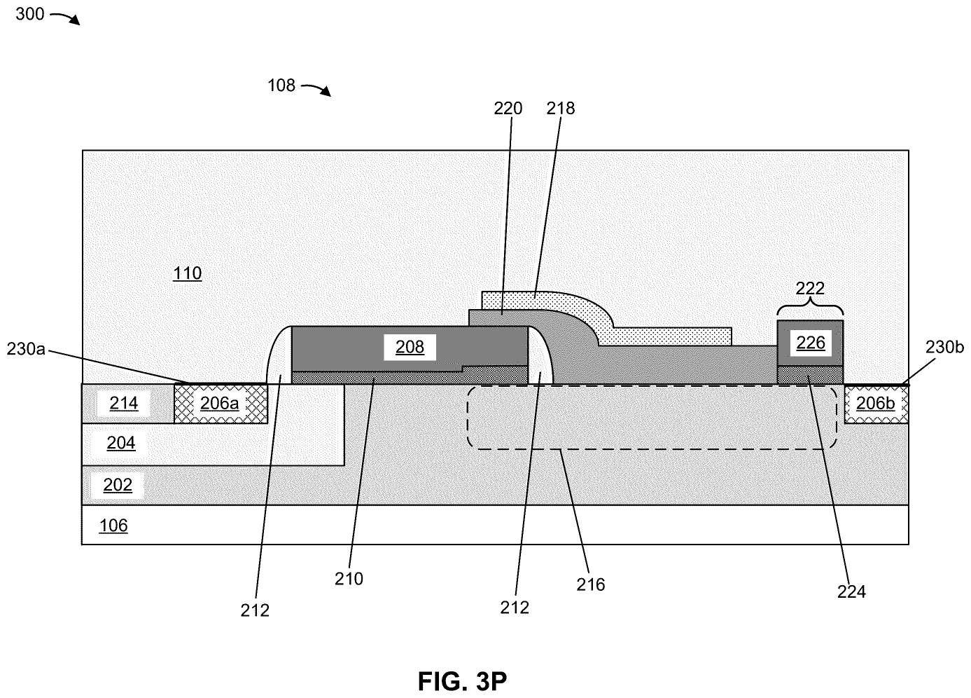

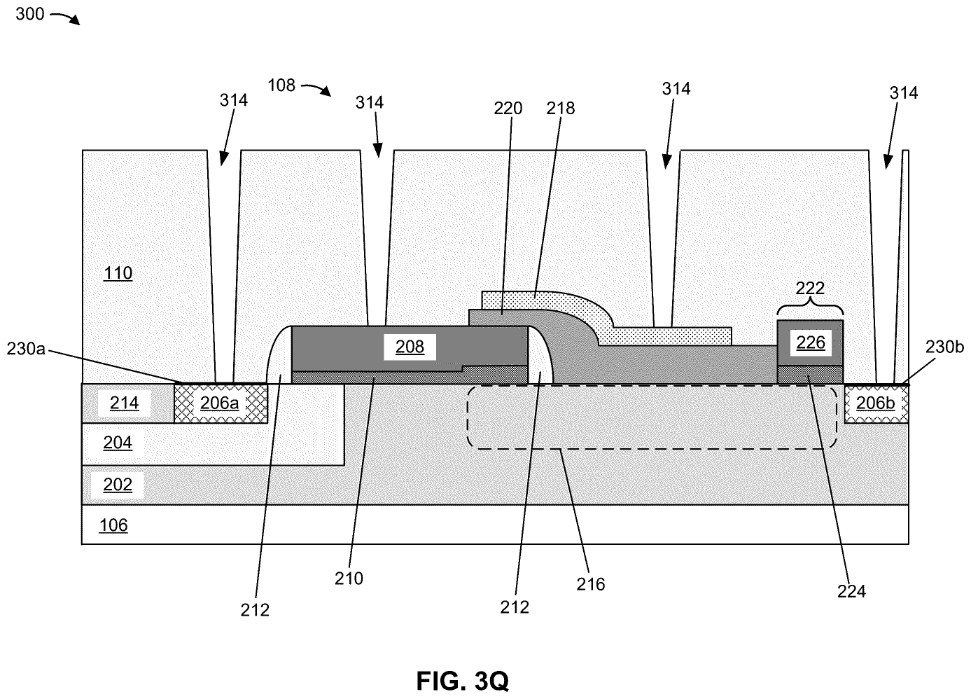

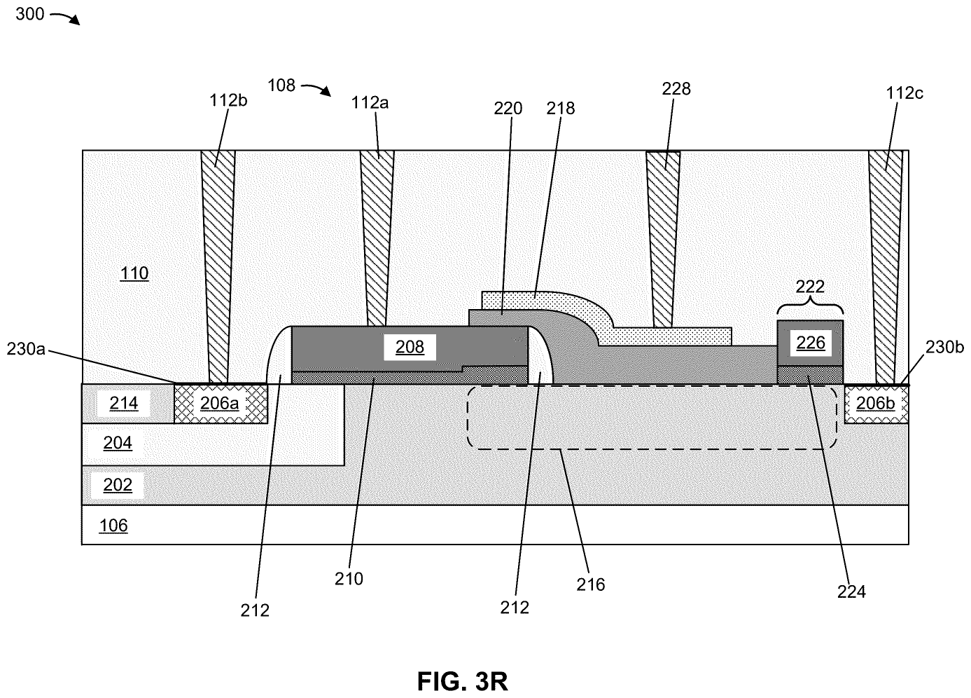

FIGS. 3A-3R are diagrams of an example implementation 300 of forming an integrated circuit device 108 that includes a main field plate layer 218 and a pattern field plate structure 222 described herein. In some implementations, one or more of the operations described in connection may be performed using one or more semiconductor processing tools, such as a deposition tool, an exposure tool, a developer tool, an etch tool, an ion implantation tool, a planarization tool, and/or another suitable semiconductor processing tool.

Turning to FIG. 3A, one or more of the operations in the example implementation 300 may be performed in connection with the substrate layer 106 of the semiconductor device 100. The substrate layer 106 may be provided in the form of a semiconductor wafer or another type of substrate.

As shown in FIG. 3B, one or more regions of the substrate layer 106 may be doped to form the active region 202 and/or to form the bulk region 204. An ion implantation tool may be used to implant dopants (e.g., p-type ions, n-type ions) into the substrate layer 106 to form the active region 202 and/or to form the bulk region 204.

As shown in FIG. 3C, a dielectric layer 302 may be formed on the substrate layer 106 and a gate electrode layer 304 may be formed on the dielectric layer 302. A deposition tool may be used to deposit the dielectric layer 302 using a physical vapor deposition (PVD) technique, a chemical vapor deposition (CVD) technique, an atomic layer deposition (ALD) technique, and/or another suitable deposition technique. In some implementations, the dielectric layer 302 is formed to have portions of different vertical thicknesses. For example, a first portion of the dielectric layer 302 may be formed to a first vertical thickness (indicated in FIG. 3C as dimension D8), and a second portion of the dielectric layer 302 may be formed to a second vertical thickness (indicated in FIG. 3C as dimension D9) that is greater than the first vertical thickness. In some implementations, the dielectric layer 302 may be deposited and then etched to form the portions having different vertical thickness. In some implementations, the portions of the dielectric layer 302 having different vertical thickness may be deposited in different deposition operations.

The gate electrode layer 304 may be formed over and/or on the dielectric layer 302. A deposition tool may be used to deposit the gate structure 208 using a PVD technique, a CVD technique, an ALD technique, an electroplating technique, and/or another suitable deposition technique. In some implementations, the dielectric layer 302 and/or the gate electrode layer 304 are planarized using a planarization tool. The dielectric layer 302 and/or the gate electrode layer 304 may be planarized using a chemical-mechanical planarization (CMP) technique and/or another suitable planarization technique.

As shown in FIG. 3D, a masking layer 306 may be formed on the gate electrode layer 304, and a pattern may be formed in the masking layer 306. In some implementations, the masking layer 306 is a photoresist layer, and a deposition tool may be used to form the masking layer 306 using a spin-coating technique and/or another suitable deposition technique. The pattern may be formed in the masking layer 306 by photolithography, where an exposure tool may be used to expose the masking layer 306 to a radiation source to pattern the masking layer 306. A developer tool may be used to develop and remove portions of the masking layer 306 to expose the pattern. In some implementations, the masking layer 306 is a hard mask layer, and an etch tool may be used to etch the masking layer 306 based on a patterned photoresist layer to form the pattern in the masking layer 306.

As shown in FIG. 3E, an etch tool may be used to etch the gate electrode layer 304 based on the pattern in the masking layer 306 to define the gate structure 208 and the metal layer 226 of the pattern field plate structure 222. In some implementations, a dry etch operation is performed to define the gate structure 208 and the metal layer 226 of the pattern field plate structure 222 such that the sidewalls of the gate structure 208 and the metal layer 226 of the pattern field plate structure 222 are substantially vertical. The dry etch operation may include a gas-based etch operation, a plasma-based etch operation, and/or another suitable dry etch operation. Additionally and/or alternatively, a wet etch operation may be performed to define the gate structure 208 and the metal layer 226 of the pattern field plate structure 222.

As shown in FIG. 3F, an etch tool may be used to etch the dielectric layer 302 based on the pattern in the masking layer 306 and/or based on the gate structure 208 and the metal layer 226 to define the gate dielectric layer 210 and the dielectric layer 224 of the pattern field plate structure 222. As indicated above, the dielectric layer 302 may include portions having different vertical thicknesses. The dielectric layer 302 may be etched such that the gate dielectric layer 210 includes a portion having the first thickness (dimension D8) and another portion having the second (greater) thickness (dimension D9). Moreover, the dielectric layer 302 may be etched such that the dielectric layer 224 of the pattern field plate structure 222 has the second (greater) thickness (dimension D9).

As shown in FIG. 3G, sidewall spacers 212 may be deposited (e.g., using a deposition tool) on the sidewalls of the gate structure 208 using a CVD technique, an ALD technique, a PVD technique, and/or another type of deposition technique. In some implementations, a spacer layer is blanket deposited over the semiconductor device 100 and then etched back to define the sidewall spacers 212.

As shown in FIG. 3H, another dielectric layer 308 may be formed over and/or on a portion of the substrate layer 106 that is between the gate structure 208 and the source/drain region 206b. The dielectric layer 308 may also be deposited over the gate structure 208, other portions of the substrate layer 106, and/or over the pattern field plate structure 222. A deposition tool may be used to deposit the dielectric layer 308 using a CVD technique, an ALD technique, a PVD technique, and/or another type of deposition technique.

As shown in FIG. 3I, an etch tool may be used to subsequently remove portions of the dielectric layer 308 to define the blocking layer 220 between the gate structure 208 and the pattern field plate structure 222. In some implementations, a dry etch operation is performed to etch the dielectric layer 308 to define the blocking layer 220. The dry etch operation may include a gas-based etch operation, a plasma-based etch operation, and/or another suitable dry etch operation. The portions of the blocking layer 220 on the pattern field plate structure 222 and on the substrate layer 106 adjacent to the side of the pattern field plate structure 222 facing away from the gate structure 208 are removed such that the pattern field plate structure 222 defines the end of the blocking layer 220 that is facing away from the gate structure 208.

As shown in FIG. 3J, the source/drain region 206a and the source/drain region 206b may be formed in the substrate layer 106. Moreover, the body implant region 214 may be formed in the substrate layer 106 next to the source/drain region 206a. The source/drain region 206a may be formed on a first side of the gate structure 208, and the source/drain region 206b may be formed on a second side of the gate structure 208 opposing the first side. Accordingly, the gate structure 208 is located laterally between the source/drain region 206a and the source/drain region 206b. This enables the gate structure 208 to selectively control the electrical conductivity of the active region 202 in the substrate layer 106 between the source/drain region 206a and the source/drain region 206b.

Moreover, the source/drain region 206b may be formed such that the pattern field plate structure 222 is located laterally between the source/drain region 206b and the blocking layer 220. The pattern field plate structure 222 provides a well-defined boundary between the edge of the source/drain region 206b and the portion of the substrate layer 106 under the pattern field plate structure 222, which enables the metal silicide layer 230b to be precisely formed on the source/drain region 206b without forming the metal silicide layer 230b on other portions of the substrate layer 106 between the source/drain region 206b and the gate structure 208.

In some implementations, the source/drain region 206a and the source/drain region 202b may be formed by doping portions of the substrate layer 106. For example, a first portion of the substrate layer 106 may be doped with one or more types of dopants (e.g., n-type dopants, p-type dopants) to form the source/drain region 206a, and a second portion of the substrate layer 106 may be doped with one or more types of dopants (e.g., n-type dopants, p-type dopants) to form the source/drain region 206b. An ion implantation tool may be used to implant dopant ions into the first portion and/or into the second portion of the substrate layer 106 to form the source/drain region 206a and/or the source/drain region 206b. Additionally and/or alternatively, another doping technique (such as diffusion) may be used to form the source/drain region 206a and the source/drain region 206b.

In some implementations, the source/drain region 206a and the source/drain region 206b are formed by epitaxially growing the source/drain region 206a and the source/drain region 206b in recesses in the substrate layer 106. An etch tool may be used to etch the substrate layer 106 to form the recesses in the substrate layer 106. The etch operation may be referred to a strained source/drain (SSD) etch operation, and the recesses may be referred to as strained source/drain recesses. In some implementations, the etch operation includes a plasma etch technique, a wet chemical etch technique, and/or another type of etch technique.

A deposition tool may be used to form the source/drain region 206a and the source/drain region 206b in the recesses. The deposition tool may be used to form the source/drain region 206a and the source/drain region 206b by epitaxial growth, in which layers of the epitaxial material are deposited in the recesses such that the layers of semiconductor material are formed by epitaxial growth in a particular crystalline orientation.

The material (e.g., silicon (Si), gallium (Ga), or another type of semiconductor material) that is used to form the source/drain region 206a and the source/drain region 206b may be doped with a p-type dopant (e.g., a type of dopant that includes electron acceptor atoms that create holes in the material), with an n-type dopant (e.g., a type of dopant that includes electron donor atoms that create mobile electrons in the material), and/or with another type of dopant. The material may be doped by adding impurities (e.g., the p-type dopant, the n-type dopant) to a source gas that is used during the epitaxial operation. Examples of p-type dopants that may be used in the epitaxial operation include boron (B) or germanium (Ge), among other examples. Examples of n-type dopants that may be used in the epitaxial operation include phosphorous (P) or arsenic (As), among other examples.

As further shown in FIG. 3K, the metal silicide layers 230a and 230b may be respectively formed on the source/drain regions 206a and 206b. A salicidation process may be performed to form the metal silicide layers 230a and 230b. The salicidation process may include using a deposition tool to deposit a layer of metal material (e.g., titanium (Ti), cobalt (Co), ruthenium (Ru)) on the source/drain regions 206a and 206b, and then performing an annealing operation to cause the metal material to diffuse into the top surface of the source/drain regions 206a and 206b to form the metal silicide layers 230a and 230b. The pattern field plate structure 222 and the blocking layer 220 block the formation of the layer of metal material (and thus, the formation of the metal silicide layer 230b) on the substrate layer 106 between the gate structure 208 and the source/drain region 206b. In some implementations, another technique is used to form the metal silicide layers 230a and 230b.

As shown in FIG. 3L, a metal-containing layer 310 may be formed over the integrated circuit device 108. A deposition tool may be used to deposit the metal-containing layer 310 using a CVD technique, an ALD technique, a PVD technique, an electroplating technique, and/or another type of deposition technique.

As shown in FIG. 3M, a photoresist layer 312 may be formed over and/or the metal-containing layer 310. A deposition tool is used to deposit the photoresist layer 312 using a spin-coating technique and/or another suitable deposition technique. The photoresist layer 312 may be patterned such that the photoresist layer 312 remains over a portion of the metal-containing layer 310 on the blocking layer 220. An exposure tool may be used to expose the photoresist layer 312 to a radiation source to pattern the photoresist layer 312. A developer tool may be used to develop and remove portions of the photoresist layer 312 to expose the pattern.

As shown in FIG. 3N, an etch operation may be performed to etch the metal-containing layer 310 based on the pattern in the photoresist layer 312 to define the main field plate layer 218. In some implementations, the etch operation may include a wet etch operation, a dry etch operation (e.g., a gas-based etch operation, a plasma-based etch operation), and/or another suitable etch operation.

As shown in FIG. 3O, the remaining portions of the photoresist layer 312 may be removed after the main field plate layer 218 is formed. In some implementations, a photoresist removal tool is used to remove the remaining portions of the photoresist layer 312 using a chemical stripper, plasma ashing, and/or another technique.

As shown in FIG. 3P, the dielectric layer 110 may be formed over and/or on the integrated circuit device 108 after the main field plate layer 218 is formed. A deposition tool may be used to deposit the dielectric layer 110 using a PVD technique, a CVD technique, an ALD technique, an oxidation technique, and/or another suitable deposition technique. In some implementations, a planarization tool is used to perform a CMP operation to planarize the dielectric layer 110.

As shown in FIG. 3Q, recesses 314 may be formed through the dielectric layer 110. For example, a recess 314 may be formed over the source/drain region 206a to expose the metal silicide layer 230a on the source/drain region 206a through the recess 314. As another example, a recess 314 may be formed over the source/drain region 206b to expose the metal silicide layer 230b on the source/drain region 206b through the recess 314. As another example, a recess 314 may be formed over the gate structure 208 to expose the gate structure 208 through the recess 314. As another example, a recess 314 may be formed over the main field plate layer 218 to expose the main field plate layer 218 through the recess 314.

In some implementations, a pattern in a photoresist layer is used to form the recesses 314. In these implementations, a deposition tool may be used to form the photoresist layer over the dielectric layer 110. An exposure tool may be used to expose the photoresist layer to a radiation source to pattern the photoresist layer. A developer tool may be used to develop and remove portions of the photoresist layer to expose the pattern. An etch tool may be used to etch through the dielectric layer 110 to form the recesses 314. In some implementations, the etch operation includes a plasma etch technique, a wet chemical etch technique, and/or another type of etch technique. In some implementations, a photoresist removal tool removes the remaining portions of the photoresist layer (e.g., using a chemical stripper, plasma ashing, and/or another technique). In some implementations, a hard mask layer is used as an alternative technique for forming the recesses 314 based on a pattern.

As shown in FIG. 3R, the contact structure 112a (e.g., a gate contact) may be formed in the recess 314 over the gate structure 208 such that the contact structure 112a lands on the gate structure 208. The contact structure 112b (e.g., a source/drain contact) may be formed in the recess 314 over the source/drain region 206a such that the contact structure 112b lands on the metal silicide layer 230a on the source/drain region 206a. The contact structure 112c (e.g., a source/drain contact) may be formed in the recess 314 over the source/drain region 206b such that the contact structure 112c lands on the metal silicide layer 230b on the source/drain region 206b. The field plate contact 228 may be formed in the recess 314 over the main field plate layer 218 such that the field plate contact 228 lands on the main field plate layer 218.

A deposition tool may be used to deposit the contact structures 112a-112c and the field plate contact 228 using a CVD technique, a PVD technique, an ALD technique, an electroplating technique, and/or another suitable deposition technique. The contact structures 112a-112c and the field plate contact 228 may be deposited in one or more deposition operations. In some implementations, a seed layer is first deposited, and the contact structures 112a-112c and the field plate contact 228 are deposited on the seed layer. In some implementations, a liner is deposited in the recesses 314, and the contact structures 112a-112c and the field plate contact 228 are deposited on the liner in the recesses 314. The liner may include a barrier liner, an adhesion liner, and/or another suitable liner. Examples of liner materials include tantalum nitride (TaN), titanium nitride (TiN), and/or other suitable liner materials. In some implementations, a planarization tool is used to perform a planarization operation (e.g., a CMP operation) to planarize the contact structures 112a-112c and the field plate contact 228 after the contact structures 112a-112c and the field plate contact 228 are deposited.

As indicated above, FIGS. 3A-3R are provided as an example. Other examples may differ from what is described with regard to FIGS. 3A-3R.

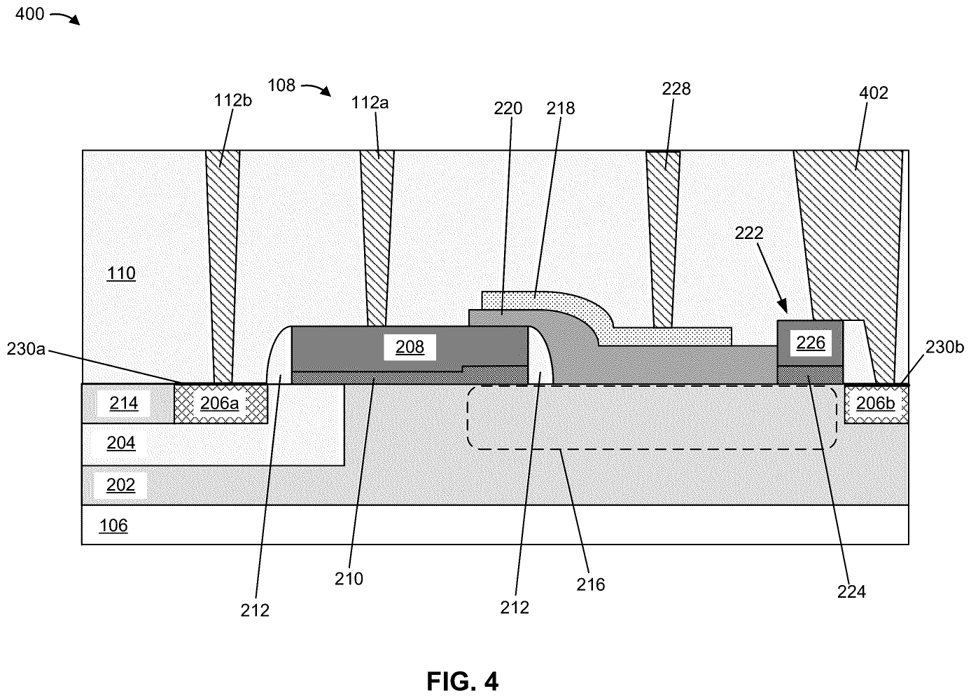

FIG. 4 is a diagram of an example implementation 400 of an integrated circuit device 108 described herein. In the example implementation 400, the integrated circuit device 108 includes a similar combination and arrangement of layers and structures as the example implementation 200 of the integrated circuit device 108 in FIGS. 2A and 2B. However, as shown in FIG. 4, the pattern field plate structure 222 is electrically shorted to the source/drain contact of the source/drain region 206b in the example implementation 400 of the integrated circuit device 108, as opposed to being an electrically floating structure in the example implementation 200 of the integrated circuit device 108. In particular, a merged contact structure 402 may be formed and included above the pattern field plate structure 222 and the source/drain region 206b, so that the pattern field plate structure 222 and the source/drain region 206b are both electrically connected to the merged contact structure 402.

As indicated above, FIG. 4 is provided as an example. Other examples may differ from what is described with regard to FIG. 4.

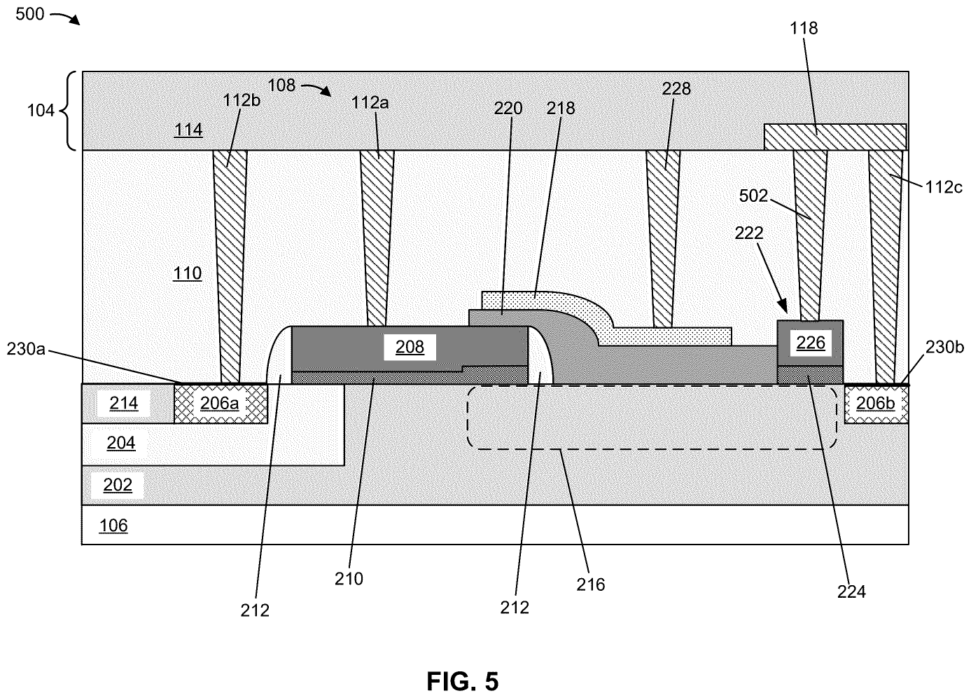

FIG. 5 is a diagram of an example implementation 500 of an integrated circuit device 108 described herein. In the example implementation 500, the integrated circuit device 108 includes a similar combination and arrangement of layers and structures as the example implementation 200 of the integrated circuit device 108 in FIGS. 2A and 2B. However, as shown in FIG. 5, the pattern field plate structure 222 is electrically shorted to the contact structure 112c of the source/drain region 206b in the example implementation 500 of the integrated circuit device 108, as opposed to being an electrically floating structure in the example implementation 200 of the integrated circuit device 108.

In particular, the pattern field plate structure 222 and the contact structure 112c of the source/drain region 206b may be electrically coupled through one or more metallization structures 118 and/or one or more interconnect structures 120 (not shown) in the interconnect layer 104 of the semiconductor device 100. In some implementations, a pattern field plate contact 502 may be included on the pattern field plate structure 222 in the dielectric layer 110, and the pattern field plate contact 502 may be electrically coupled to the contact structure 112c through the one or more metallization structures 118 and/or the one or more interconnect structures 120 in the interconnect layer 104.

As indicated above, FIG. 5 is provided as an example. Other examples may differ from what is described with regard to FIG. 5.

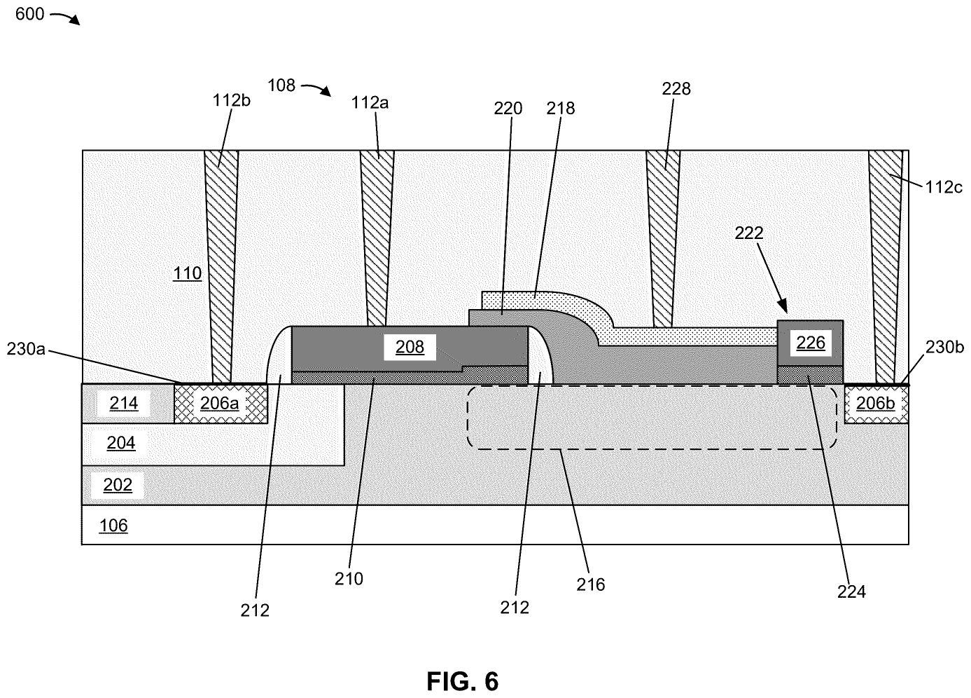

FIG. 6 is a diagram of an example implementation 600 of an integrated circuit device 108 described herein. In the example implementation 600, the integrated circuit device 108 includes a similar combination and arrangement of layers and structures as the example implementation 200 of the integrated circuit device 108 in FIGS. 2A and 2B. However, as shown in FIG. 6, the pattern field plate structure 222 is electrically shorted to the main field plate layer 218 in the example implementation 600 of the integrated circuit device 108, as opposed to being an electrically floating structure in the example implementation 200 of the integrated circuit device 108. Thus, the edge of the pattern field plate structure 222 facing the gate structure 208 may be in direct physical contact with the edge of the main field plate layer 218 facing the source/drain region 206b.

As indicated above, FIG. 6 is provided as an example. Other examples may differ from what is described with regard to FIG. 6.

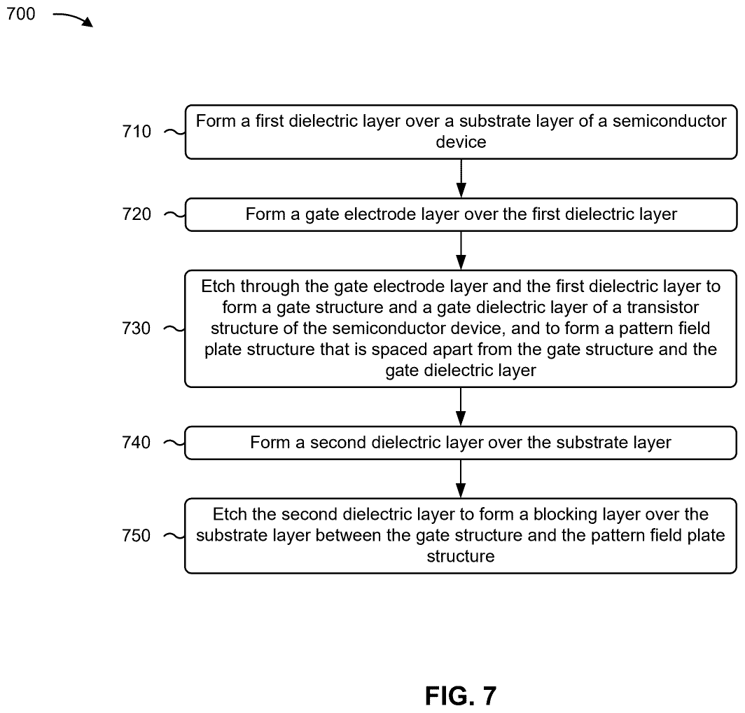

FIG. 7 is a flowchart of an example process 700 associated with forming a semiconductor device described herein. In some implementations, one or more process blocks of FIG. 7 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 7, process 700 may include forming a first dielectric layer over a substrate layer of a semiconductor device (block 710). For example, one or more semiconductor processing tools may be used to form a first dielectric layer (e.g., a dielectric layer 302) over a substrate layer (e.g., a substrate layer 106) of a semiconductor device (e.g., a semiconductor device 100), as described herein.

As further shown in FIG. 7, process 700 may include forming a gate electrode layer over the first dielectric layer (block 720). For example, one or more semiconductor processing tools may be used to form a gate electrode layer (e.g., a gate electrode layer 304) over the first dielectric layer, as described herein.

As further shown in FIG. 7, process 700 may include etching through the gate electrode layer and the first dielectric layer to form a gate structure and a gate dielectric layer of a transistor structure of the semiconductor device, and to form a pattern field plate structure that is spaced apart from the gate structure and the gate dielectric layer (block 730). For example, one or more semiconductor processing tools may be used to etch through the gate electrode layer and the first dielectric layer to form a gate structure (e.g., a gate structure 208) and a gate dielectric layer (e.g., a gate dielectric layer 210) of a transistor structure of the semiconductor device, and to form a pattern field plate structure (e.g., a pattern field plate structure 222) that is spaced apart from the gate structure and the gate dielectric layer, as described herein.

As further shown in FIG. 7, process 700 may include forming a second dielectric layer over the substrate layer (block 740). For example, one or more semiconductor processing tools may be used to form a second dielectric layer (e.g., a dielectric layer 308) over the substrate layer, as described herein.

As further shown in FIG. 7, process 700 may include etching the second dielectric layer to form a blocking layer over the substrate layer between the gate structure and the pattern field plate structure (block 750). For example, one or more semiconductor processing tools may be used to etch the second dielectric layer to form a blocking layer (e.g., a blocking layer 220) over the substrate layer between the gate structure and the pattern field plate structure, as described herein.

Process 700 may include additional implementations, such as any single implementation or any combination of implementations described below and/or in connection with one or more other processes described elsewhere herein.

In a first implementation, etching the second dielectric layer includes etching the second dielectric layer using the gate structure and the pattern field plate structure as a self-aligned mask.

In a second implementation, alone or in combination with the first implementation, process 700 includes forming, in the substrate layer, a first source/drain region (e.g., a source/drain region 206a) adjacent to the gate structure, and forming, in the substrate layer, a second source/drain region (e.g., a source/drain region 206b) adjacent to the pattern field plate structure.

In a third implementation, alone or in combination with one or more of the first and second implementations, process 700 includes forming a metal silicide layer (e.g., a metal silicide layer 220b) on the second source/drain region, where the blocking layer and the pattern field plate structure block the metal silicide layer from being formed in the substrate layer between the gate structure and the second source/drain region.

In a fourth implementation, alone or in combination with one or more of the first through third implementations, process 700 includes forming a main field plate layer (e.g., a main field plate layer 218) on the blocking layer such that the main field plate layer is spaced apart from the pattern field plate structure.

Although FIG. 7 shows example blocks of process 700, in some implementations, process 700 includes additional blocks, fewer blocks, different blocks, or differently arranged blocks than those depicted in FIG. 7. Additionally, or alternatively, two or more of the blocks of process 700 may be performed in parallel.

In this way, a high-voltage transistor includes a main field plate layer between a gate structure and a drain region of the high-voltage transistor, a blocking layer between the main field plate layer and a substrate layer of the high-voltage transistor, and a pattern field plate structure laterally between the blocking layer and the drain region. The pattern field plate structure may be formed from the same layer(s) as the gate structure and associated gate dielectric layer, which minimizes the cost, complexity, and manufacturing resources for forming the pattern field plate structure. The pattern field plate structure functions as a self-aligned mask for forming the blocking layer, the drain region, and/or a metal silicide layer on the drain region. This enables closer positioning of the blocking layer and a drain contact on the drain region, as well as a reduced lateral size of the drain region, which enables a smaller lateral footprint to be achieved for the high-voltage transistor without increasing (or with minimal increase) to the peak electric field between the gate structure and the drain region of the high-voltage transistor.

As described in greater detail above, some implementations described herein provide a semiconductor device. The semiconductor device includes a first source/drain region in a substrate layer. The semiconductor device includes a second source/drain region in the substrate layer. The semiconductor device includes a gate structure above the substrate and between the first source/drain region and the second source/drain region. The semiconductor device includes a blocking layer on a first portion of the substrate layer, where the blocking layer is located between the gate structure and the second source/drain region. The semiconductor device includes a main field plate layer on the blocking layer. The semiconductor device includes a pattern field plate structure on a second portion of the substrate layer, where the pattern field plate structure is located laterally between the blocking layer and the second source/drain region.

As described in greater detail above, some implementations described herein provide a method. The method includes forming a first dielectric layer over a substrate layer of a semiconductor device. The method includes forming a gate electrode layer over the first dielectric layer. The method includes etching through the gate electrode layer and the first dielectric layer to form a gate structure and a gate dielectric layer of a transistor structure of the semiconductor device, and to form a pattern field plate structure that is spaced apart from the gate structure and the gate dielectric layer. The method includes forming a second dielectric layer over the substrate layer. The method includes etching the second dielectric layer to form a blocking layer over the substrate layer between the gate structure and the pattern field plate structure.

As described in greater detail above, some implementations described herein provide a semiconductor device. The semiconductor device includes a first source/drain region in a substrate layer. The semiconductor device includes a second source/drain region in the substrate layer. The semiconductor device includes a gate structure above the substrate layer and between the first source/drain region and the second source/drain region. The semiconductor device includes a gate dielectric layer between the gate structure and the substrate layer. The semiconductor device includes a sidewall spacer on a sidewall of the gate structure. The semiconductor device includes a blocking layer on a first portion of the substrate layer, where the blocking layer is located between the sidewalls spacer and the second source/drain region, and where a first end of the blocking layer is located over the gate structure. The semiconductor device includes a main field plate layer on the blocking layer. The semiconductor device includes a pattern field plate structure on a second portion of the substrate layer, where the pattern field plate structure is located laterally between the blocking layer and the second source/drain region, and where a second end of the blocking layer, opposing the first end, is in physical contact with the pattern field plate structure.

The terms “approximately” and “substantially” can indicate a value of a given quantity that varies within 5% of the value (e.g., ±1%, ±2%, ±3%, ±4%, ±5% of the value). These values are merely examples and are not intended to be limiting. It is to be understood that the terms “approximately” and “substantially” can refer to a percentage of the values of a given quantity in light of this disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a first source/drain region in a substrate layer;
a second source/drain region in the substrate layer;
a gate structure above the substrate and between the first source/drain region and the second source/drain region;
a blocking layer on a first portion of the substrate layer,
wherein the blocking layer is located between the gate structure and the second source/drain region;
a main field plate layer on the blocking layer; and
a pattern field plate structure on a second portion of the substrate layer,
wherein the pattern field plate structure is located laterally between the blocking layer and the second source/drain region.

2. The semiconductor device of claim 1, wherein the pattern field plate structure comprises:
a dielectric layer on the second portion of the substrate layer; and
a metal layer on the dielectric layer.

3. The semiconductor device of claim 1, wherein the pattern field plate structure is spaced apart from the main field plate layer.

4. The semiconductor device of claim 1, wherein the main field plate layer is in contact with the pattern field plate structure.

5. The semiconductor device of claim 1, wherein the pattern field plate structure is electrically isolated from the second source/drain region.

6. The semiconductor device of claim 1, wherein the pattern field plate structure is electrically connected to the second source/drain region.

7. The semiconductor device of claim 6, wherein the pattern field plate structure is electrically connected to the second source/drain region through a merged contact structure.

8. The semiconductor device of claim 6, wherein the pattern field plate structure is electrically connected to the second source/drain region through a backend metallization layer in an interconnect layer of the semiconductor device.

9. The semiconductor device of claim 1, wherein the blocking layer is in contact with the pattern field plate structure.

10. A method, comprising:
forming a first dielectric layer over a substrate layer of a semiconductor device;
forming a gate electrode layer over the first dielectric layer;
etching through the gate electrode layer and the first dielectric layer to form a gate structure and a gate dielectric layer of a transistor structure of the semiconductor device, and to form a pattern field plate structure that is spaced apart from the gate structure and the gate dielectric layer;
forming a second dielectric layer over the substrate layer; and
etching the second dielectric layer to form a blocking layer over the substrate layer between the gate structure and the pattern field plate structure.

11. The method of claim 10, wherein etching the second dielectric layer comprises:
etching the second dielectric layer using the gate structure and the pattern field plate structure as a self-aligned mask.

12. The method of claim 10, further comprising:
forming, in the substrate layer, a first source/drain region adjacent to the gate structure; and
forming, in the substrate layer, a second source/drain region adjacent to the pattern field plate structure.

13. The method of claim 12, further comprising:
forming a metal silicide layer on the second source/drain region,
wherein the blocking layer and the pattern field plate structure block the metal silicide layer from being formed in the substrate layer between the gate structure and the second source/drain region.

14. The method of claim 10, further comprising:
forming a main field plate layer on the blocking layer such that the main field plate layer is spaced apart from the pattern field plate structure.

15. A semiconductor device, comprising:
a first source/drain region in a substrate layer;
a second source/drain region in the substrate layer;
a gate structure above the substrate layer and between the first source/drain region and the second source/drain region;
a gate dielectric layer between the gate structure and the substrate layer;
a sidewall spacer on a sidewall of the gate structure;
a blocking layer on a first portion of the substrate layer,
wherein the blocking layer is located between the sidewalls spacer and the second source/drain region, and
wherein a first end of the blocking layer is located over the gate structure;
a main field plate layer on the blocking layer; and
a pattern field plate structure on a second portion of the substrate layer,
wherein the pattern field plate structure is located laterally between the blocking layer and the second source/drain region, and
wherein a second end of the blocking layer, opposing the first end, is in physical contact with the pattern field plate structure.

16. The semiconductor device of claim 15, wherein a length of the pattern field plate structure is less than a length of the gate structure.

17. The semiconductor device of claim 16, wherein a distance between the pattern field plate structure and the sidewall spacer is less than a distance between the second source/drain region and the gate structure.

18. The semiconductor device of claim 15, further comprising:
a contact structure on a body implant region that is laterally adjacent to, and electrically connected to, the second source/drain region,
wherein a distance between the pattern field plate structure and the main field plate layer is less than a distance between the pattern field plate structure and the contact structure.

19. The semiconductor device of claim 15, wherein the pattern field plate structure comprises:
a dielectric layer on the second portion of the substrate layer; and
a metal layer on the dielectric layer.

20. The semiconductor device of claim 19, wherein the dielectric layer and the gate dielectric layer comprise a same first material composition; and
wherein the gate structure and the metal layer comprise a same second material composition.
